(19) United States
(12) Patent Application Publication
(10) Pub. No.: US 2018/0269416 A1
(43) Pub. Date: Sep. 20, 2018

(54) LIGHT-EMITTING ELEMENT, LIGHT-EMITTING DEVICE, LIGHT SOURCE, AUTHENTICATION DEVICE, AND ELECTRONIC APPARATUS

(71) Applicant: SEIKO EPSON CORPORATION, Tokyo (JP)

(72) Inventors: Yuiga HAMADE, Fujimi-machi (JP); Tetsuji FUJITA, Chino-shi (JP)

(73) Assignee: SEIKO EPSON CORPORATION, Tokyo (JP)

(21) Appl. No.: 15/914,080

(22) Filed: Mar. 7, 2018

(30) Foreign Application Priority Data
Mar. 14, 2017 (JP) 2017-048284

(51) Int. Cl. H01L 51/50

(52) U.S. Cl. CPC H01L 51/5004; H01L 51/5012; H01L 27/3244; H01L 2251/552; H01L 2251/558; H01L 51/5084

(57) ABSTRACT

A light-emitting element according to the invention includes an anode, a cathode, a light-emitting layer which is provided between the anode and the cathode, contains a light-emitting material and a first tetracene-based compound having a tetracene skeleton functioning as a host material that holds the light-emitting material, and emits light in a wavelength region of 600 nm or more by applying a current between the anode and the cathode, and an electron transport layer which is provided between the light-emitting layer and the cathode, and includes a first electron transport layer located on the cathode side and a second electron transport layer located on the light-emitting layer side and containing a second tetracene-based compound having a tetracene skeleton.

### BACKGROUND

### 1. Technical Field

The present invention relates to a light-emitting element, a light-emitting device, a light source, an authentication device, and an electronic apparatus.

### 2. Related Art

An organic electroluminescence element (so-called organic EL element) is a light-emitting element having a structure in which at least one layer of a luminous organic layer is interposed between an anode and a cathode. In such a light-emitting element, by applying an electric field between the cathode and the anode, an electron is injected into a light-emitting layer from the cathode side and also a hole is injected into the light-emitting layer from the anode side, and the electron and the hole are recombined in the light-emitting layer, whereby an exciton is generated, and energy generated when this exciton is returned to a ground state is released as light.

As such a light-emitting element, there is known a light-emitting element which emits light in a long wavelength region exceeding 600 nm, particularly in a near-infrared region exceeding 700 nm (see, for example, JP-A-2012-219078 (Patent Document 1) or JP-A-2016-15423 (Patent Document 2)).

In a light-emitting element disclosed in Patent Document 1, by using a thiadiazole-based dopant material and a tetracene-based host material in a light-emitting layer, the emission wavelength is shifted to a longer wavelength, and also a light-emitting element which has high efficiency and a long lifetime is realized.

In a light-emitting element disclosed in Patent Document 2, in which the light-emitting element includes a light-emitting layer containing a thiadiazole-based dopant material or the like, by devising the element configuration other than the light-emitting layer, particularly, the element configuration of an electron transport layer and an electron injection layer, the emission wavelength is shifted to a longer wavelength, and also a light-emitting element which has high efficiency and a long lifetime is realized.

Further, in the light-emitting elements disclosed in Patent Documents 1 and 2, also by using a tetracene-based host material as a host material of the light-emitting layer, high efficiency and a long lifetime of the light-emitting element are achieved.

However, in such a light-emitting element, high efficiency and a long lifetime of the light-emitting element described above are achieved by using a tetracene-based host material as a host material of the light-emitting layer, however, a HOMO gap is present on a boundary surface between the light-emitting layer (host material) and the electron transport layer, and holes jump over the gap, and therefore, the light-emitting element has a problem that the driving voltage is increased, and also the power consumption is increased.

### SUMMARY

An advantage of some aspects of the invention is to provide a light-emitting element, in which suppression of power consumption is achieved as the driving voltage is decreased, and a light-emitting device, a light source, an authentication device, and an electronic apparatus, each of which includes this light-emitting element.

The advantage can be achieved by the following configurations.

A light-emitting element according to an aspect of the invention includes an anode, a cathode, a light-emitting layer which is provided between the anode and the cathode, contains a light-emitting material and a first tetracene-based compound having a tetracene skeleton functioning as a host material that holds the light-emitting material, and emits light in a wavelength region of 600 nm or more by applying a current between the anode and the cathode, and an electron transport layer which is provided between the light-emitting layer and the cathode, and includes a first electron transport layer located on the cathode side and a second electron transport layer located on the light-emitting layer side and containing a second tetracene-based compound having a tetracene skeleton.

According to this configuration, the driving voltage of the light-emitting element can be decreased, and as a result, the light-emitting element in which the power consumption is suppressed can be realized.

In the light-emitting element according to the aspect of the invention, it is preferred that the first tetracene-based compound and the second tetracene-based compound are the same or of the same type.

According to this configuration, the HOMO level of the second electron transport layer and the HOMO level of the host material contained in the light-emitting layer can be more reliably made equal or close to each other. Therefore, the driving voltage of the light-emitting element is decreased, and as a result, the light-emitting element in which the power consumption is suppressed is realized.

In the light-emitting element according to the aspect of the invention, it is preferred that the first tetracene-based compound and the second tetracene-based compound each have a tetracene skeleton with no heterocyclic skeleton.

According to this configuration, the resistance to oxidation and reduction due to injection of holes becomes relatively strong, and therefore, alteration or deterioration due to holes can be suppressed. As a result, the lifetime of the light-emitting element is extended.

In the light-emitting element according to the aspect of the invention, it is preferred that the first electron transport layer contains an anthracene-based compound having an anthracene skeleton and a nitrogen-containing heterocyclic skeleton, and has an average thickness of less than 8 nm.

According to this configuration, alteration or deterioration of the first electron transport layer can be suppressed. As a result, the lifetime of the light-emitting element is extended.

In the light-emitting element according to the aspect of the invention, it is preferred that a difference between the HOMO of the first tetracene-based compound and the HOMO of the second tetracene-based compound is 0.1 eV or less.

According to this configuration, it can be said that the HOMO level of the second electron transport layer and the HOMO level of the host material contained in the light-emitting layer are equal or close to each other, and as a result, the driving voltage of the light-emitting element is decreased, and therefore, the light-emitting element in which the power consumption is suppressed is realized.

In the light-emitting element according to the aspect of the invention, it is preferred that the second electron transport layer has an average thickness of 25 nm or more and 200 nm or less.

According to this configuration, the second electron transport layer can be favorably made to exhibit both functions as an electron transport layer for transporting electrons to the first electron transport layer and as a hole transport layer for transporting holes having passed through the light-emitting layer to the first electron transport layer.

In the light-emitting element according to the aspect of the invention, it is preferred that the light-emitting element is used by applying a current between the anode and the cathode at a current density of 500 mA/cm² or more and 2000 mA/cm² or less.

Even if a current is applied at such a current density, the alteration or deterioration of the electron transport layer is suppressed, and thus, the light-emitting element in which the lifetime is extended can be achieved.

A light-emitting device according to an aspect of the invention includes the light-emitting element according to the aspect of the invention.

Such a light-emitting device can emit light in a near-infrared region. Further, the light-emitting device includes the light-emitting element in which the power consumption is suppressed, and therefore has excellent reliability.

A light source according to an aspect of the invention includes the light-emitting element according to the aspect of the invention.

Such a light source can emit light in a near-infrared region. Further, the light source includes the light-emitting element in which the power consumption is suppressed, and therefore has excellent reliability.

An authentication device according to an aspect of the invention includes the light-emitting element according to the aspect of the invention.

Such an authentication device enables biometric authentication using near-infrared light. Further, the authentication device includes the light-emitting element in which the power consumption is suppressed, and therefore has excellent reliability.

An electronic apparatus according to an aspect of the invention includes the light-emitting element according to the aspect of the invention.

Such an electronic apparatus includes the light-emitting element in which the power consumption is suppressed, and therefore has excellent reliability.

### BRIEF DESCRIPTION OF THE DRAWINGS

The invention will be described with reference to the accompanying drawings, wherein like numbers reference like elements.

FIG. 1 is a cross-sectional view schematically showing a light-emitting element according to an embodiment of the invention.

FIG. 2 is a longitudinal cross-sectional view showing an embodiment of a display device to which a light-emitting device according to the invention is applied.

FIG. 3 is a view showing an embodiment of an authentication device according to the invention.

FIG. 4 is a perspective view showing the configuration of a mobile-type (or notebook-type) personal computer to which an electronic apparatus according to the invention is applied.

### DESCRIPTION OF EXEMPLARY EMBODIMENTS

Hereinafter, a light-emitting element, a light-emitting device, a light source, an authentication device, and an electronic apparatus according to the invention will be described with reference to preferred embodiments shown in the accompanying drawings.

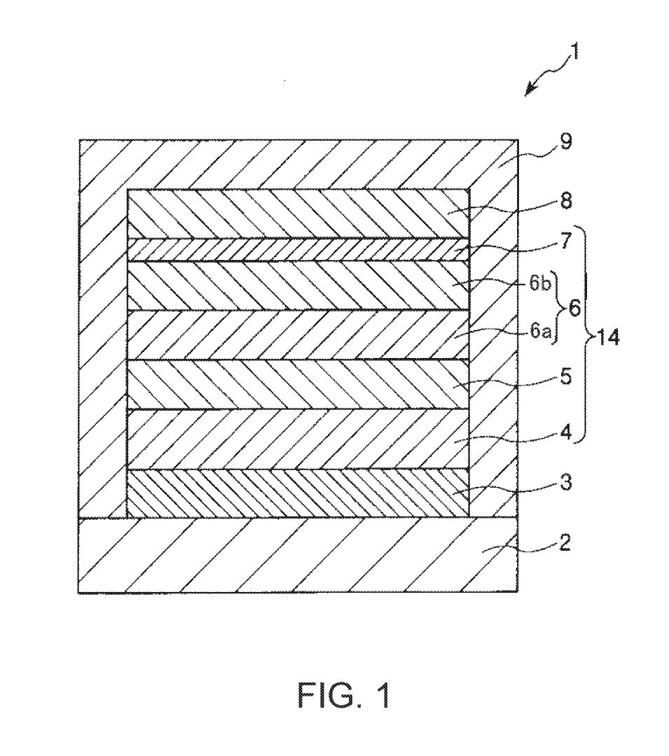

FIG. 1 is a cross-sectional view schematically showing a light-emitting element according to an embodiment of the invention. Hereinafter, for the sake of convenience of explanation, a description will be given by referring to the upper side and the lower side in FIG. 1 as “upper” and “lower”, respectively.

In this embodiment, as shown in FIG. 1, a light-emitting element (electroluminescence element) 1 is constituted by stacking an anode 3, a hole injection layer 4, a light-emitting layer 5, an electron transport layer 6, an electron injection layer 7, and a cathode 8 in this order. That is, the light-emitting element 1 includes the anode 3, the cathode 8, and a stacked body 14, which is interposed between the anode 3 and the cathode 8, and in which the hole injection layer 4, the light-emitting layer 5, the electron transport layer 6, and the electron injection layer 7 are stacked in this order from the anode 3 side to the cathode 8 side.

The entire light-emitting element 1 is provided on a substrate 2 and sealed with a sealing member 9.

Such a light-emitting element 1 includes the anode 3, the cathode 8, and the light-emitting layer 5 provided between the anode 3 and the cathode 8. By applying a driving voltage to the anode 3 and the cathode 8 so as to apply a current between the anode 3 and the cathode 8, that is, to the light-emitting layer 5, an electron is supplied (injected) to the light-emitting layer 5 from the cathode 8 side, and also a hole is supplied (injected) to the light-emitting layer 5 from the anode 3 side. Then, the hole and the electron are recombined in the light-emitting layer 5, and an exciton is generated by energy released at the time of this recombination, and when the exciton is returned to a ground state, energy (fluorescence or phosphorescence) is released (light is emitted). In this manner, the light-emitting element 1 (light-emitting layer 5) emits light.

In this embodiment, as described later, this light-emitting element 1 contains a thiadiazole-based compound which is a compound represented by the following general formula (IRD1), a benzo-bis-thiadiazole-based compound which is a compound represented by the following general formula (IRD2), and a pyrromethene-based boron complex which is a compound represented by the following formula (IRD3) or the like as light-emitting materials. According to this, the light-emitting element 1 emits light in a near-infrared region such as a wavelength region of 700 nm or more. The “near-infrared region” as used herein refers to a wavelength region of 700 nm or more and 1500 nm or less. The light-emitting element 1 may contain a compound which emits light in a yellow (including orange) to red wavelength region of 600 nm or more and less than 700 nm as the light-emitting material. That is, in the invention, the light-emitting element 1 emits light in a wavelength region of 600 nm or more.

The substrate 2 supports the anode 3. The light-emitting element 1 of this embodiment is configured to extract light from the substrate 2 side (bottom emission type), and therefore, the substrate 2 and the anode 3 are each configured to be substantially transparent (colorless and transparent, colored and transparent, or semi-transparent).

Examples of the constituent material of the substrate 2 include resin materials such as polyethylene terephthalate, polyethylene naphthalate, polypropylene, a cycloolefin polymer, polyamide, polyether sulfone, polymethyl methacrylate, polycarbonate, and polyarylate, and glass materials such as quartz glass and soda glass, and among these, it is possible to use one type or two or more types in combination.

The average thickness of such a substrate 2 is not particularly limited, but is preferably about 0.1 mm or more and 30 mm or less, more preferably about 0.1 mm or more and 10 mm or less.

In a case where the light-emitting element 1 is configured to extract light from the side opposite to the substrate 2 (top emission type), both a transparent substrate and a non-transparent substrate can be used as the substrate 2.

Examples of the non-transparent substrate include a substrate constituted by a ceramic material such as alumina, a substrate having an oxide film (insulating film) formed on the surface of a metal substrate such as stainless steel, and a substrate constituted by a resin material.

Further, in such a light-emitting element 1, the distance between the anode 3 and the cathode 8 (that is, the average thickness of the stacked body 14) is preferably 100 nm or more and 500 nm or less, more preferably 100 nm or more and 300 nm or less, further more preferably 100 nm or more and 250 nm or less. According to this, the driving voltage of the light-emitting element 1 can be easily and reliably decreased within a practical range.

Hereinafter, the respective sections constituting the light-emitting element 1 will be sequentially described.

### Anode

The anode 3 is an electrode which injects holes into the hole injection layer 4. As the constituent material of the anode 3, a material having a large work function and excellent electrical conductivity is preferably used.

Examples of the constituent material of the anode 3 include oxides such as ITO (Indium Tin Oxide), IZO (Indium Zinc Oxide), In₂O₃, SnO₂, Sb-doped SnO₂, and Al-doped ZnO, Au, Pt, Ag, Cu, and an alloy containing any of these metals, and among these, it is possible to use one type or two or more types in combination.

In particular, the anode 3 is preferably constituted by ITO. ITO is a material which is transparent, and also has a large work function and excellent electrical conductivity. According to this, holes can be efficiently injected from the anode 3 into the hole injection layer 4.

Further, it is preferred that the surface of the anode 3 on the hole injection layer 4 side (the upper surface in FIG. 1) is subjected to a plasma treatment. According to this, the chemical and mechanical stability of the joining surface of the anode 3 and the hole injection layer 4 can be increased. As a result, the hole injection property from the anode 3 into the hole injection layer 4 can be improved. Such a plasma treatment will be described in detail in the description of the below-mentioned production method for the light-emitting element 1.

The average thickness of such an anode 3 is not particularly limited, but is preferably about 10 nm or more and 200 nm or less, more preferably about 50 nm or more and 150 nm or less.

### Cathode

The cathode 8 is an electrode which injects electrons into the electron transport layer 6 through the below-mentioned electron injection layer 7. As the constituent material of the cathode 8, a material having a small work function is preferably used.

Examples of the constituent material of the cathode 8 include Li, Mg, Ca, Sr, La, Ce, Er, Eu, Sc, Y, Yb, Ag, Cu, Al, Cs, Rb, and an alloy containing any of these metals, and among these, it is possible to use one type or two or more types in combination (for example, as a stacked body of a plurality of layers, a mixed layer of a plurality of types, or the like).

In particular, in a case where an alloy is used as the constituent material of the cathode 8, it is preferred to use an alloy containing a stable metal element such as Ag, Al, or Cu, specifically, an alloy such as MgAg, AlLi, or CuLi. By using such an alloy as the constituent material of the cathode 8, the electron injection efficiency and stability of the cathode 8 can be improved.

The average thickness of such a cathode 8 is not particularly limited, but is preferably about 100 nm or more and 10000 nm or less, more preferably about 100 nm or more and 500 nm or less.

The light-emitting element 1 of this embodiment is of a bottom emission type, and therefore, a light transmission property is not particularly required for the cathode 8. In a case where the light-emitting element 1 is of a top emission type, it is necessary that light be transmitted from the cathode 8 side, and therefore, the average thickness of the cathode 8 is preferably about 1 nm or more and 50 nm or less.

### Hole Injection Layer

The hole injection layer 4 has a function to improve the hole injection efficiency from the anode 3 (that is, has a hole injection property). According to this, the luminous efficiency of the light-emitting element 1 can be increased. Here, the hole injection layer 4 also has a function to transport holes injected from the anode 3 to the light-emitting layer 5 (that is, has a hole transport property). Therefore, since the hole injection layer 4 has a hole transport property as described above, it can also be said that the hole injection layer 4 is a hole transport layer. A hole transport layer constituted by a material different from that of the hole injection layer 4 (for example, an amine-based compound such as a benzidine derivative) may be separately provided between the hole injection layer 4 and the light-emitting layer 5.

This hole injection layer 4 contains a material having a hole injection property (a hole injection material).

The hole injection material contained in this hole injection layer 4 is not particularly limited, and examples thereof include copper phthalocyanine and amine-based materials such as 4,4′,4″-tris(N,N-phenyl-3-methylphenylamino)triphenylamine (m-MTDATA) and N,N′-bis-(4-diphenylamino-phenyl)-N,N′-diphenyl-biphenyl-4-4′-diamine.

Above all, as the hole injection material contained in the hole injection layer 4, from the viewpoint of excellent hole injection property and hole transport property, it is preferred to use an amine-based material, and it is more preferred to use a diaminobenzene derivative, a benzidine derivative (a material having a benzidine skeleton), a triamine-based compound and a tetraamine-based compound, each having both a “diaminobenzene” unit and a “benzidine” unit in the molecule (specifically, for example, compounds represented by the following formulae HIL-1 to HIL-27).

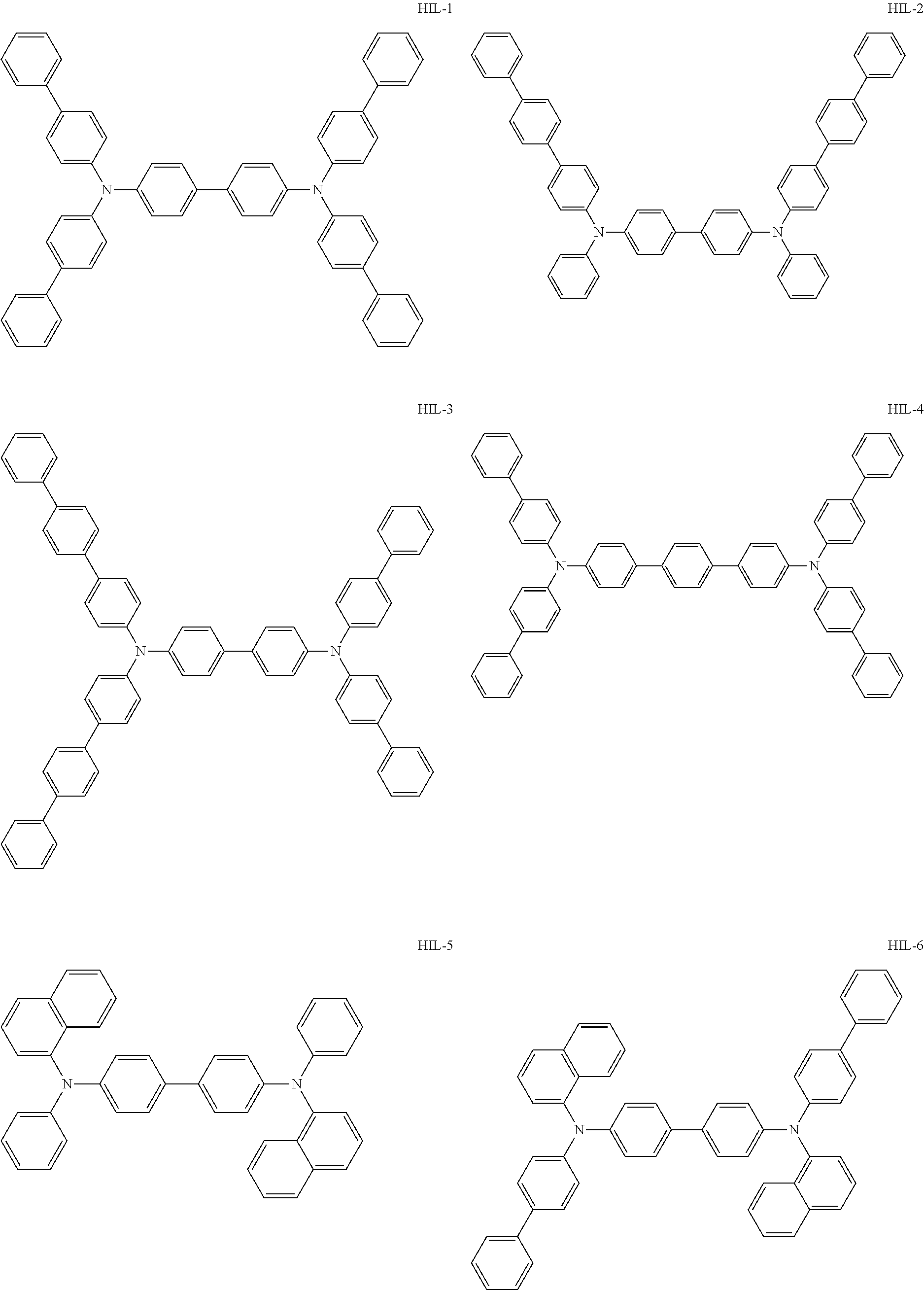

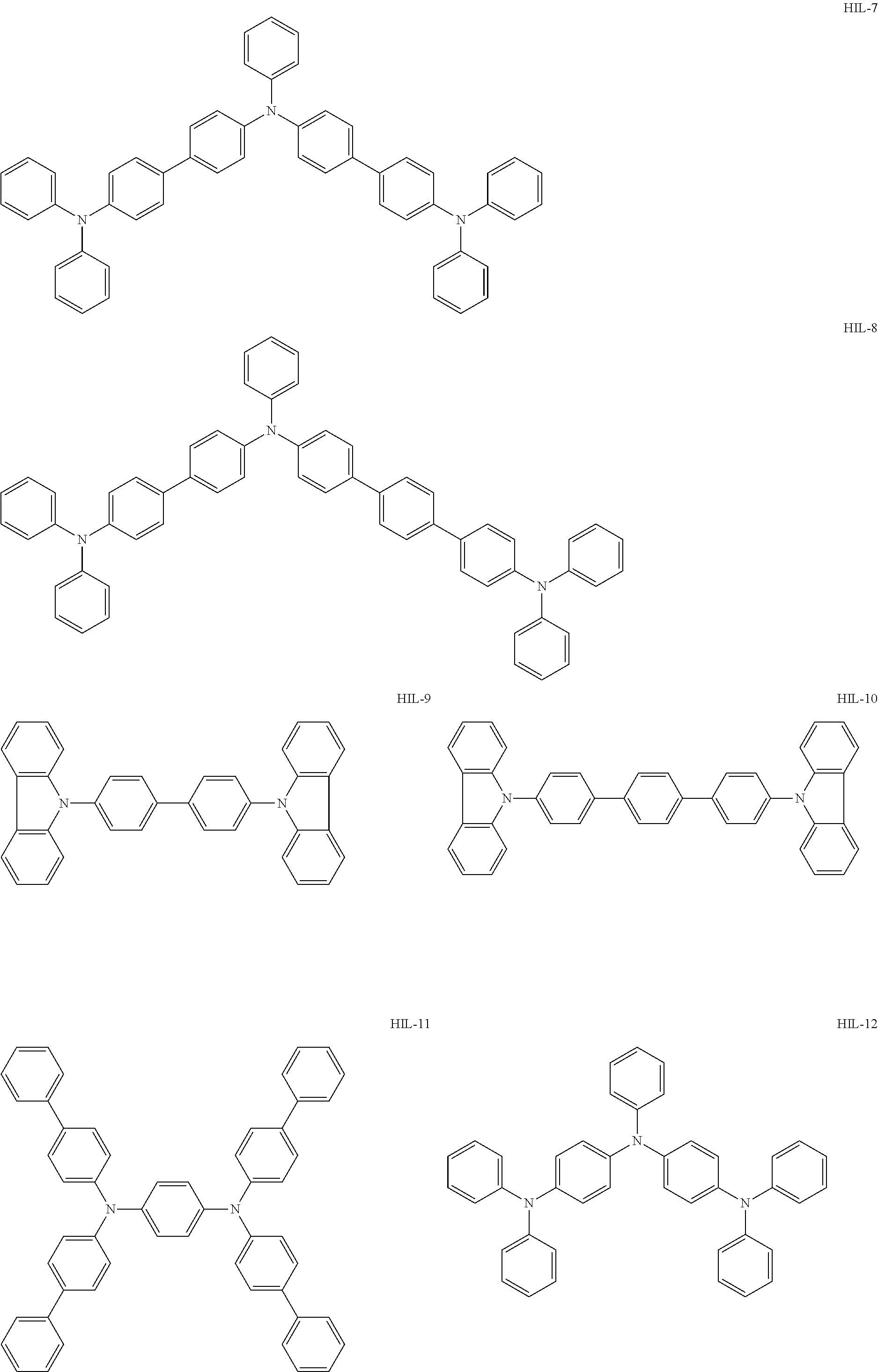

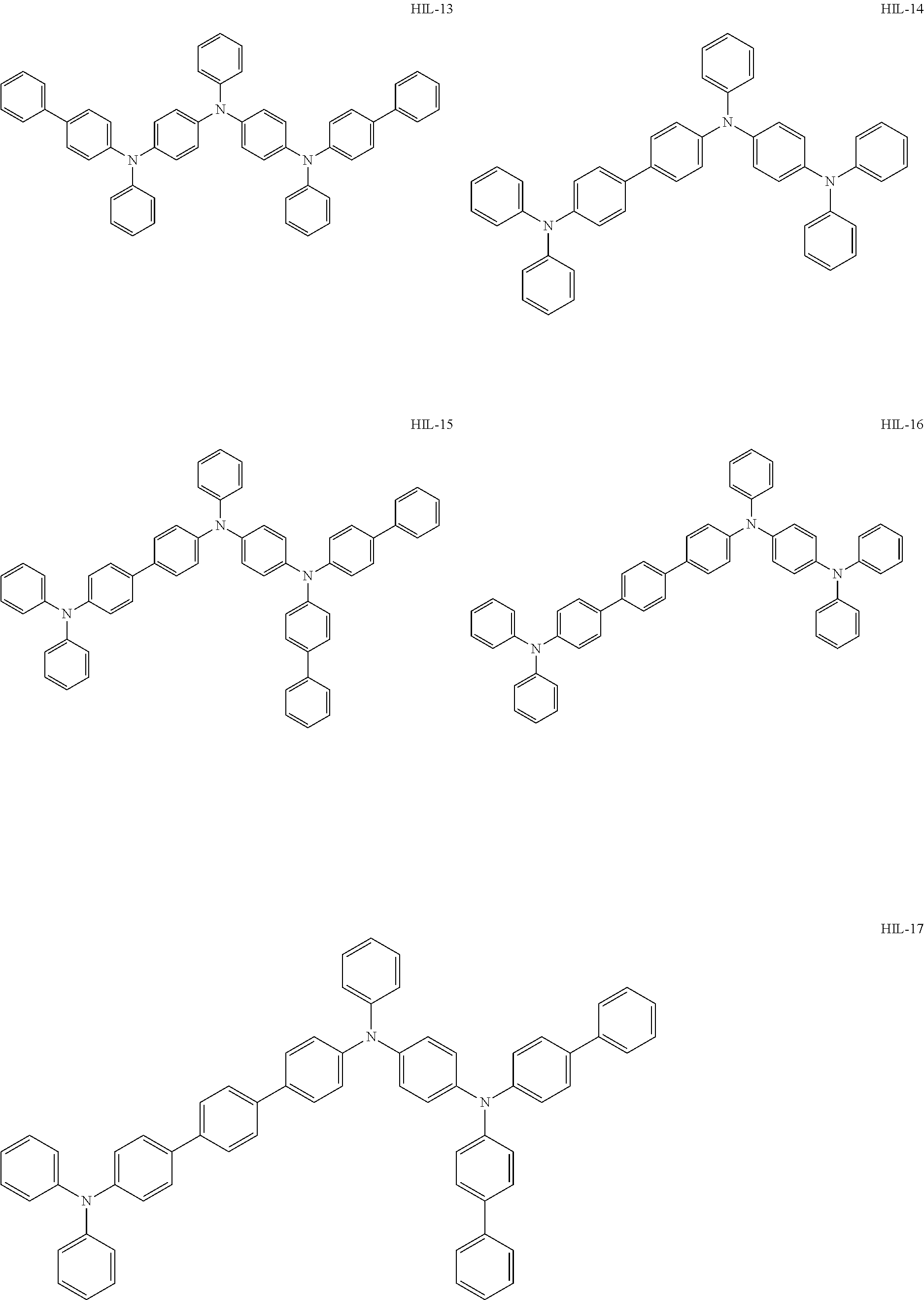 [SMILES: c1ccc(-c2ccc(N(c3ccccc3)c3ccc(N(c4ccccc4)c4ccc(N(c5ccccc5)c5ccc(-c6ccccc6)cc5)cc4)cc3)cc2)cc1 ; c1ccc(N(c2ccccc2)c2ccc(-c3ccc(N(c4ccccc4)c4ccc(N(c5ccccc5)c5ccccc5)cc4)cc3)cc2)cc1 ; c1ccc(-c2ccc(N(c3ccc(-c4ccccc4)cc3)c3ccc(N(c4ccccc4)c4ccc(-c5ccc(N(c6ccccc6)c6ccccc6)cc5)cc4)cc3)cc2)cc1 ; c1ccc(N(c2ccccc2)c2ccc(-c3ccc(-c4ccc(N(c5ccccc5)c5ccc(N(c6ccccc6)c6ccccc6)cc5)cc4)cc3)cc2)cc1 ; c1ccc(-c2ccc(N(c3ccc(-c4ccccc4)cc3)c3ccc(N(c4ccccc4)c4ccc(-c5ccc(-c6ccc(N(c7ccccc7)c7ccccc7)cc6)cc5)cc4)cc3)cc2)cc1]

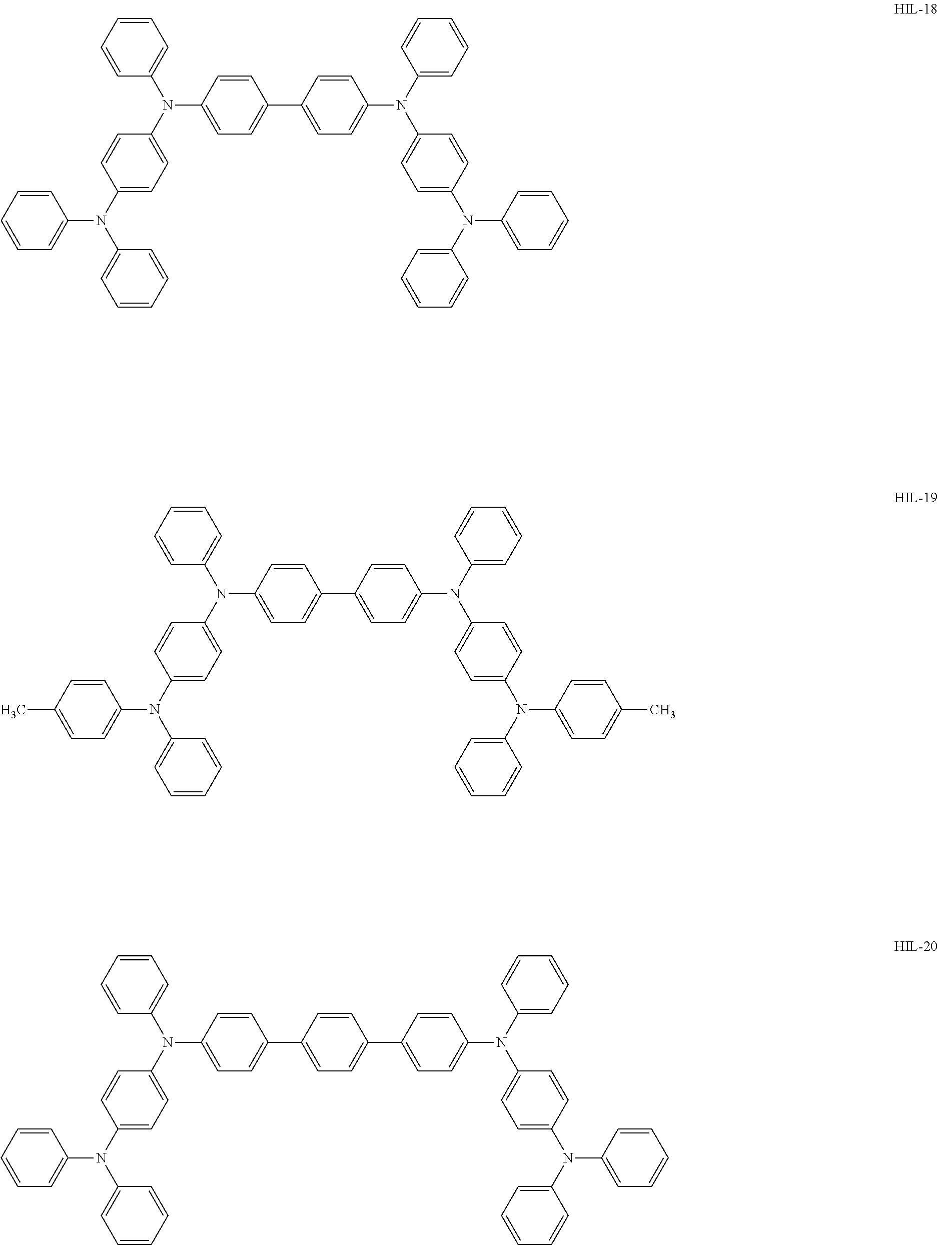

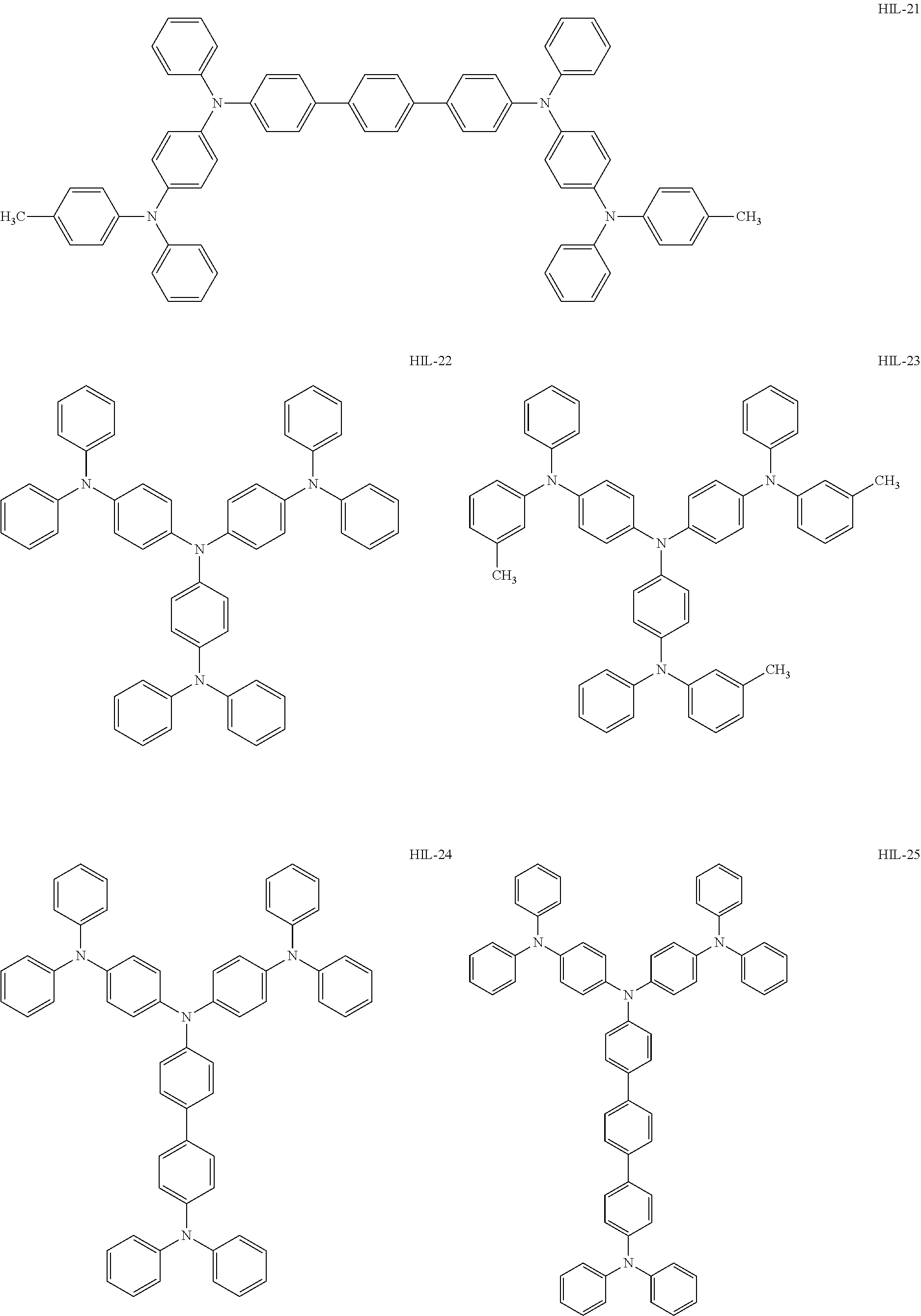

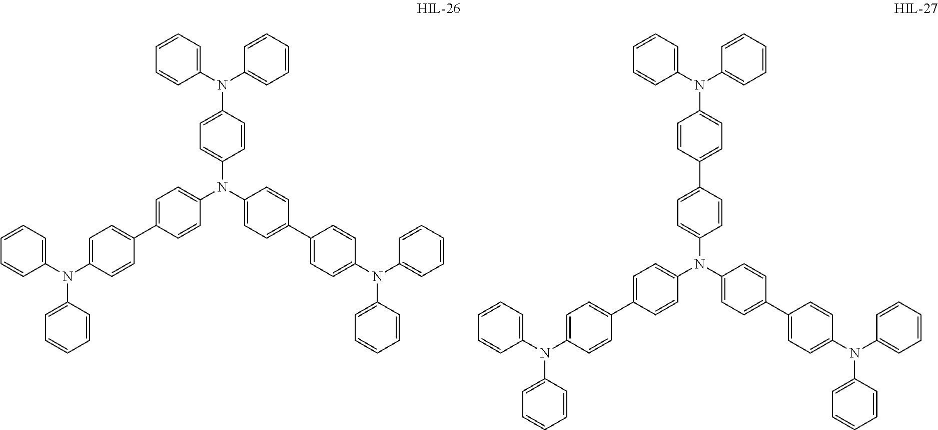 [SMILES: c1ccc(N(c2ccccc2)c2ccc(-c3ccc(N(c4ccc(-c5ccc(N(c6ccccc6)c6ccccc6)cc5)cc4)c4ccc(N(c5ccccc5)c5ccccc5)cc4)cc3)cc2)cc1 ; c1ccc(N(c2ccccc2)c2ccc(-c3ccc(N(c4ccc(-c5ccc(N(c6ccccc6)c6ccccc6)cc5)cc4)c4ccc(-c5ccc(N(c6ccccc6)c6ccccc6)cc5)cc4)cc3)cc2)cc1]

It is preferred that a difference between the LUMO of the constituent material of the hole injection layer 4 and the LUMO of a host material to be used in the light-emitting layer 5 is 0.5 eV or more. According to this, electrons coming out of the light-emitting layer 5 to the hole injection layer are reduced, and thus, the luminous efficiency can be increased.

Further, the HOMO of the constituent material of the hole injection layer 4 is preferably 4.7 eV or more and 5.8 eV or less, and the LUMO of the constituent material of the hole injection layer 4 is preferably 2.2 eV or more and 3.0 eV or less.

In addition, the hole injection layer 4 is preferably constituted by further including a second tetracene-based compound contained in the below-mentioned second electron transport layer 6a other than the material having a hole injection property (hole injection material). According to this, even if an electron comes out of the light-emitting layer 5 and the electron is injected into the hole injection layer 4, the electron can be transported by the second tetracene-based compound, and therefore, the alteration or deterioration of the material having a hole injection property due to the injected electron can be suppressed or prevented. As a result, the lifetime of the light-emitting element 1 can be extended.

The average thickness of such a hole injection layer 4 is not particularly limited, but is preferably about 5 nm or more and 90 nm or less, more preferably about 10 nm or more and 70 nm or less.

This hole injection layer 4 may be omitted depending on the combination of the constituent materials of other layers or the like.

### Light-Emitting Layer

The light-emitting layer 5 emits light by applying a current between the anode 3 and the cathode 8 described above.

In the invention, the light-emitting layer 5 contains a light-emitting material functioning as a light-emitting dopant and a first tetracene-based compound having a tetracene skeleton functioning as a host material that holds the light-emitting material.

In the light-emitting layer 5, the light-emitting material is constituted by including a material which enables the light-emitting layer 5 to emit light in a long wavelength region of 600 nm or more, preferably in a near-infrared region of 700 nm or more.

Examples of the light-emitting material in a case where the light-emitting layer 5 is enabled to emit light in a near-infrared region of 700 nm or more include a thiadiazole-based compound which is a compound represented by the following general formula (IRD1) (hereinafter also simply referred to as “thiadiazole-based compound”), a benzo-bis-thiadiazole-based compound which is a compound represented by the following general formula (IRD2) (hereinafter also simply referred to as “benzo-bis-thiadiazole-based compound”), and a pyrromethene-based boron complex which is a compound represented by the following formula (IRDS) (hereinafter also simply referred to as “pyrromethene-based boron complex”), and among these, it is possible to use one type or two or more types in combination. According to this, the light-emitting layer 5 can be reliably made to emit light in a wavelength region of 700 nm or more (in a near-infrared region).

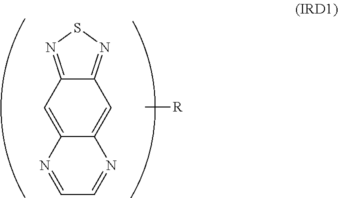

In the general formula (IRD1), R each independently represents an aryl group, an arylamino group, triarylamine, or a group containing at least one of the derivatives thereof.

Examples of the group R in the general formula (IRD1) include an aryl group, an arylamino group, triarylamine, and derivatives thereof, and it is possible to use a combination of two or more types among these. The light-emitting layer 5 containing the thiadiazole-based compound including such a group R as a light-emitting dopant can emit light in a wavelength region of 700 nm or more (in a near-infrared region).

Specific examples of the thiadiazole-based compound including the group R as described above include compounds represented by the following formulae IRD1-1 to IRD1-12 and derivatives thereof.

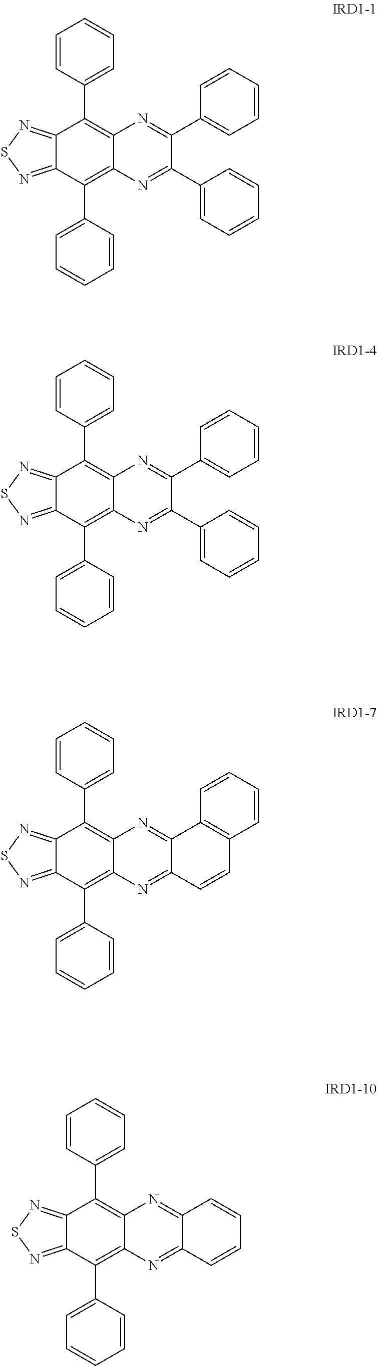 [SMILES: c1ccc(-c2nc3c(-c4ccccc4)c4nsnc4c(-c4ccccc4)c3nc2-c2ccccc2)cc1 ; c1ccc(-c2nc3c(-c4ccccc4)c4nsnc4c(-c4ccccc4)c3nc2-c2ccccc2)cc1 ; c1ccc(-c2c3nsnc3c(-c3ccccc3)c3nc4c(ccc5ccccc54)nc23)cc1 ; c1ccc(-c2c3nsnc3c(-c3ccccc3)c3nc4ccccc4nc23)cc1]

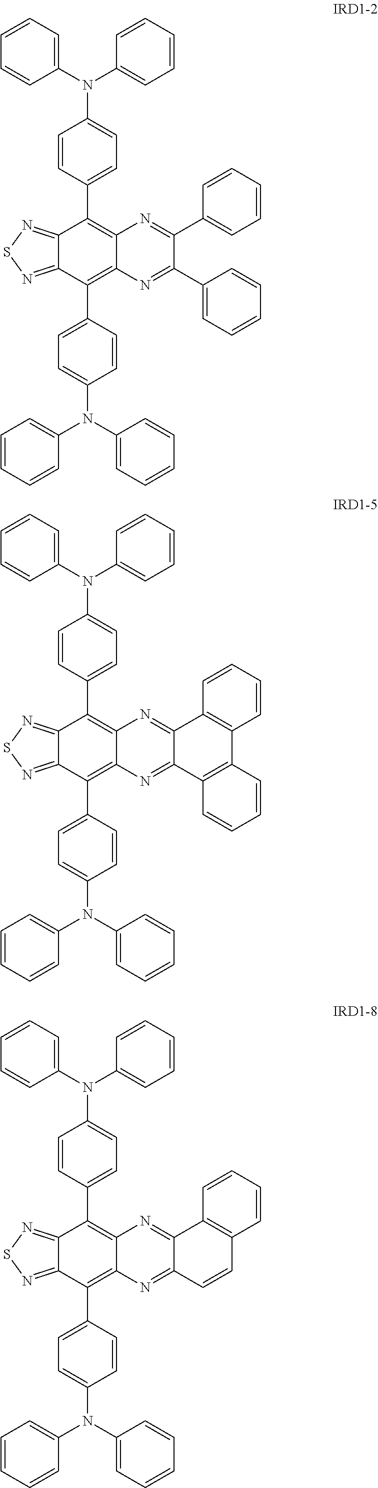

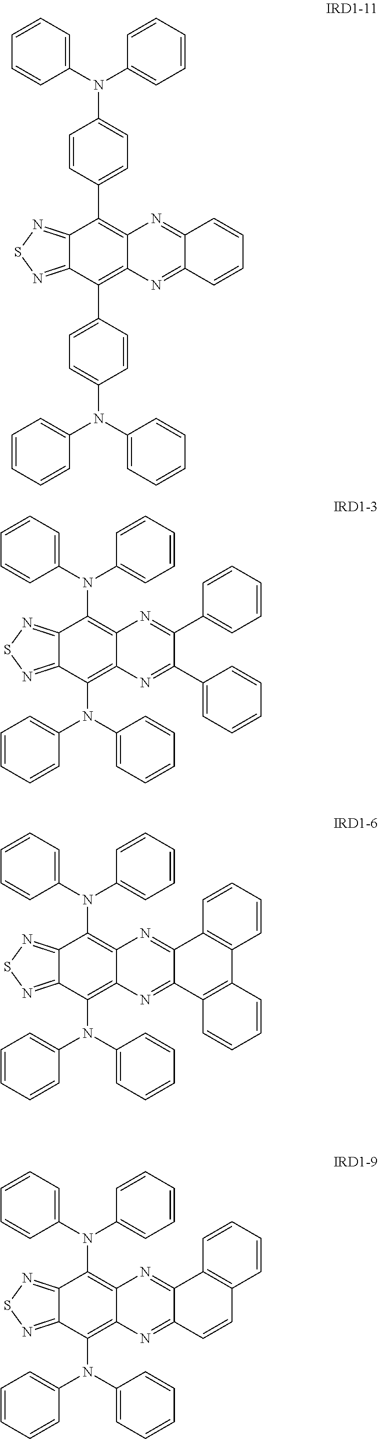

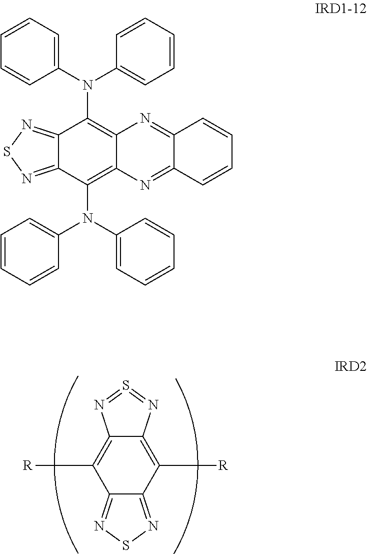

In the general formula (IRD2), each R independently represents a phenyl group, a thiophenyl group, a furyl group, or a group containing at least one of the derivatives thereof.

Each group R in the general formula (IRD2) is not particularly limited as long as it is a phenyl group, a thiophenyl group, a furyl group, or a group containing at least one of the derivatives thereof, however, for example, a group which contains a phenyl group, a thiophenyl group (thiophene group), a furyl group (furan group), an oxazole group, and an oxadiazole group or the like is exemplified, and the group R is preferably a group in which two or more types among these are combined. According to this, the light-emitting layer 5 containing the benzo-bis-thiadiazole-based compound including such a group R as a light-emitting dopant can emit light in a wavelength region of 700 nm or more (in a near-infrared region), particularly can emit light in a wavelength region of 850 nm or more and 1500 nm or less, which can be said to be a longer wavelength region.

Specific examples of the benzo-bis-thiadiazole-based compound including the group R as described above include compounds represented by the following formulae IRD2-1 to IRD2-21 and derivatives thereof.

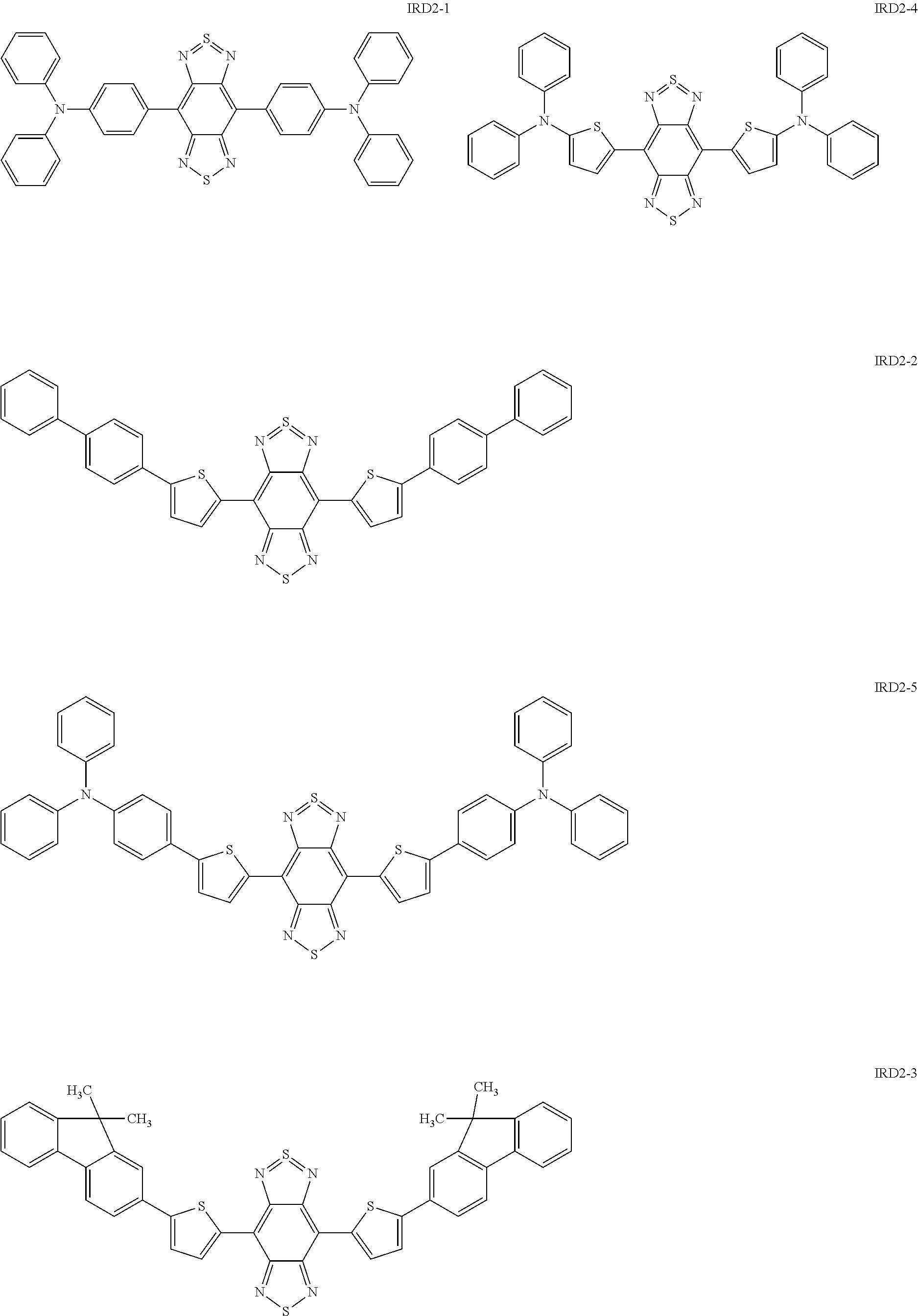

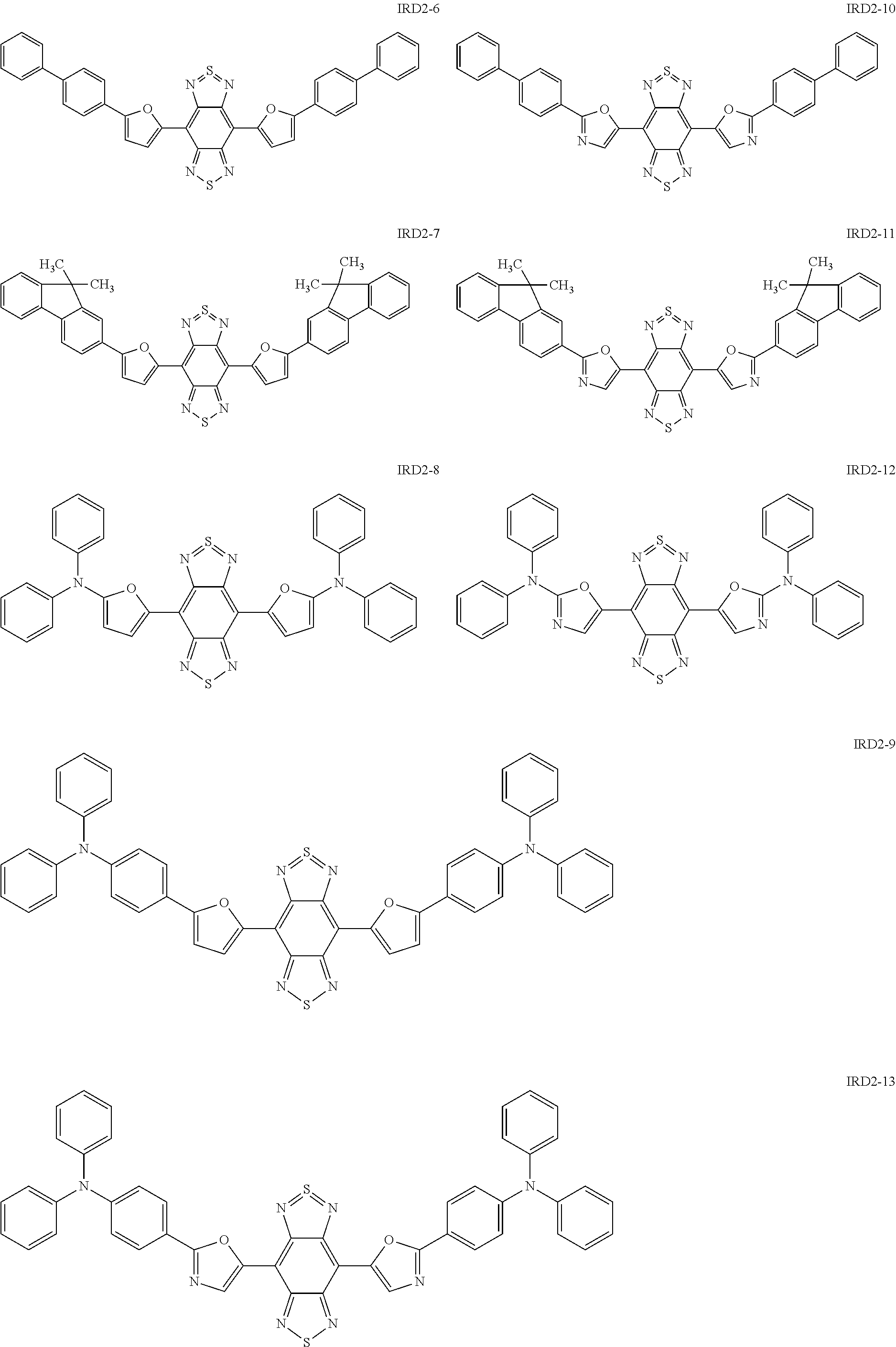

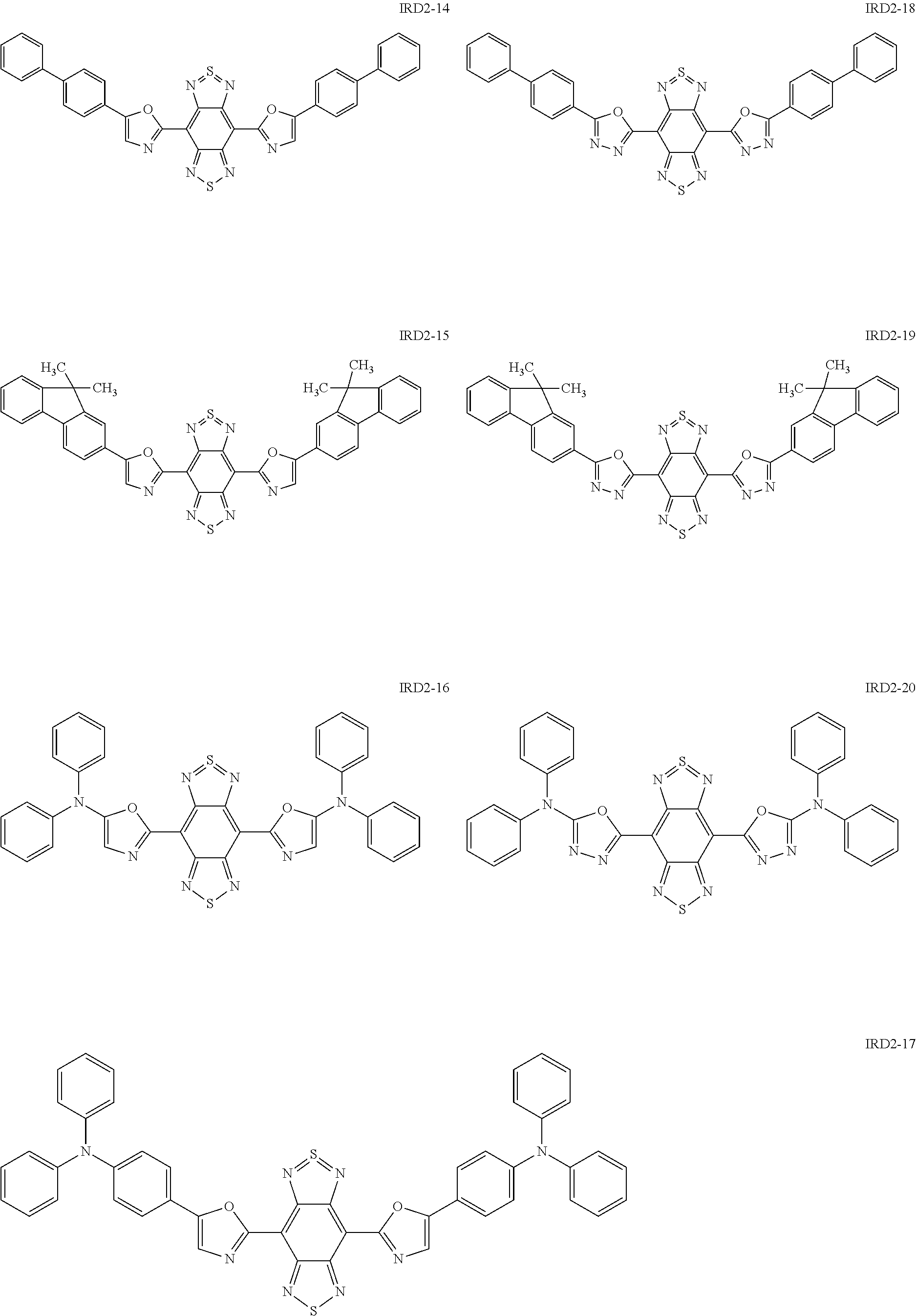

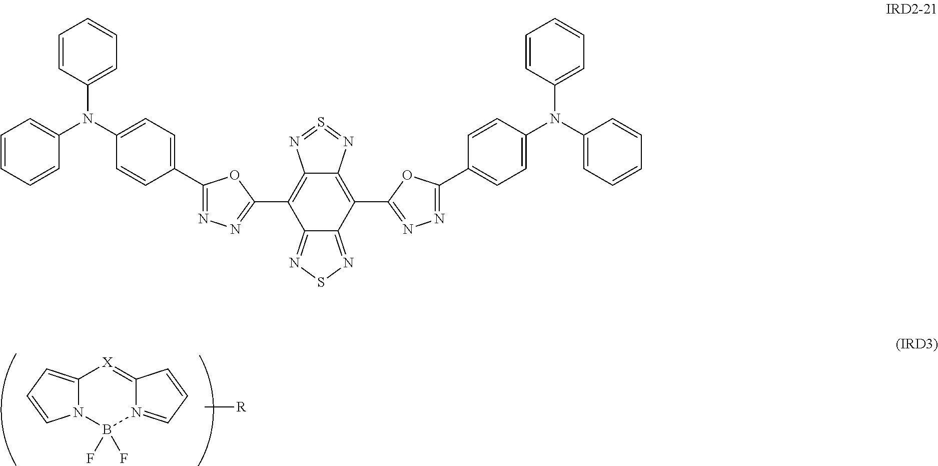

In the formula (IRD3), X represents a carbon atom to which hydrogen is attached or a nitrogen atom, and R represents a hydrogen atom, an alkyl group, an aryl group which may have a substituent, an allyl group, an alkoxy group, or a heterocyclic group.

Here, the heterocyclic group to be used as R in the formula (IRDS) is not particularly limited, however, it is preferred to use a 5-membered heterocyclic group such as pyrrole, furan, or thiophene, or a 6-membered heterocyclic group such as pyridine.

The light-emitting layer 5 containing such a pyrromethene-based boron complex can emit light in a wavelength region of 700 nm or more (in a near-infrared region).

Further, the light-emitting material to be used in the light-emitting layer 5 may be any as long as it is a compound represented by the above formula (IRD3) and can emit light in a near-infrared region, however, specific examples thereof include compounds represented by the following formulae IRD3-1 to IRD3-5 and derivatives thereof.

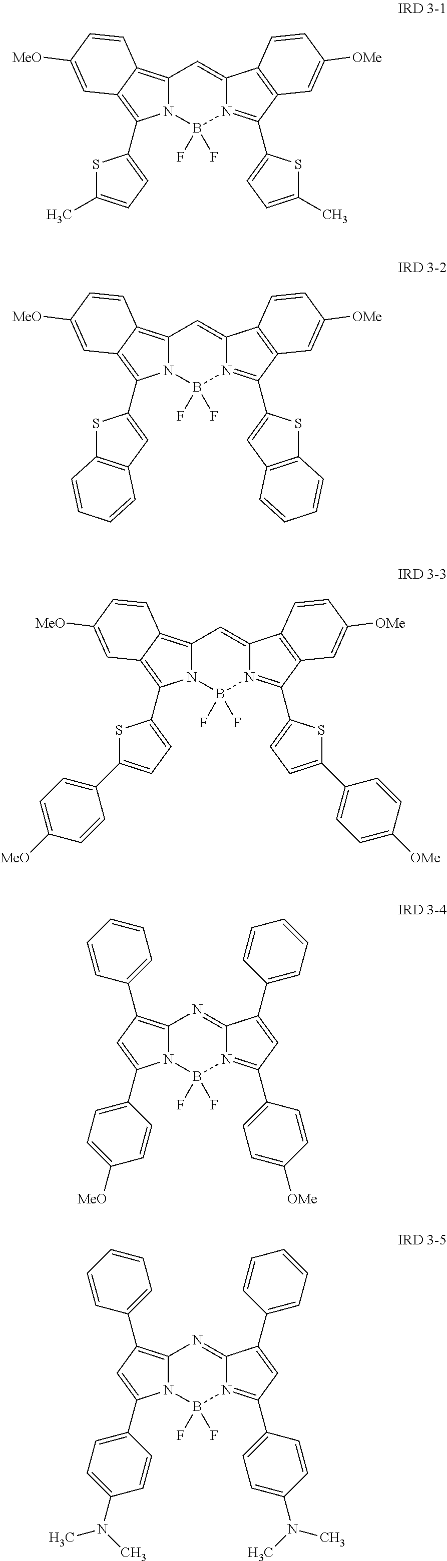

In a case where the light-emitting layer 5 is made to emit light in a yellow (including orange) to red wavelength region of 600 nm or more and less than 700 nm, examples of the light-emitting material include a red light-emitting material and a yellow light-emitting material as shown below.

Examples of the red light-emitting material include perylene derivatives such as a compound (diindenoperylene derivative) represented by the following chemical formula (RD-1), europium complexes, benzopyran derivatives, rhodamine derivatives, benzothioxanthene derivatives, porphyrin derivatives, nile red, 2-((1,1-dimethylethyl)-6-(2-(2,3,6,7-tetrahydro-1,1,7,7-tetramethyl-1H,5H-benzo(ij)quinolizin-9-yl)ethenyl)-4H-pyran-4H-ylidene)propanedinitrile (DCJTB), and 4-(dicyanomethylene)-2-methyl-6-(p-dimethylaminostyryl)-4H-pyran (DCM). Examples of the yellow light-emitting material include a tetracene-based compound represented by the following chemical formula (YD-1) and tetraphenylnaphthacene (commonly known as rubrene).

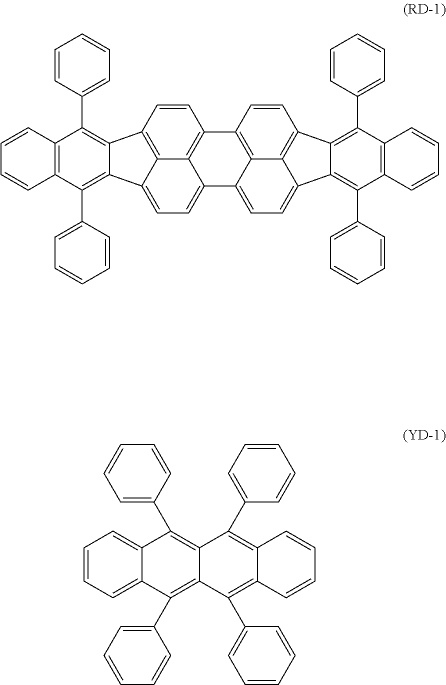

The light-emitting layer 5 may contain another light-emitting material (any of various types of fluorescent materials and various types of phosphorescent materials) other than the above-mentioned light-emitting materials.

Further, the light-emitting layer 5 is configured to contain, in addition to the light-emitting material as described above, a host material to which this light-emitting material is added (supported) as a guest material (dopant). This host material has a function to recombine a hole and an electron to generate an exciton, and also to transfer the energy of the exciton (Forster-transfer or Dexter-transfer) to the light-emitting material to excite the light-emitting material. Due to this, by configuring the light-emitting layer 5 to contain the host material in addition to the light-emitting material (guest material), the luminous efficiency of the light-emitting element 1 can be increased. Such a host material can be used by, for example, doping the light-emitting material which is the guest material as the dopant into the host material.

As such a host material, the first tetracene-based compound having a tetracene skeleton is contained in the invention.

An acene-based material such as this first tetracene-based compound has fewer undesirable interactions with the guest material (light-emitting material) as described above. Further, when the first tetracene-based material is used as the host material, the energy transfer from the host material to the guest material (light-emitting material) can be efficiently achieved. Due to this, the luminous efficiency of the light-emitting element 1 can be made excellent. This is considered to be because the overlap of the π electron cloud of the acene-based material with the electron cloud of the guest material is increased, and so on.

Accordingly, when the first tetracene-based compound is used as the host material, the luminous efficiency of the light-emitting element 1 can be increased.

In addition, the first tetracene-based compound has excellent resistance to electrons and holes. Further, the first tetracene-based compound also has excellent thermal stability. Due to this, not only the lifetime of the light-emitting layer 5, but also the lifetime of the light-emitting element 1 can be extended. Further, the first tetracene-based compound has excellent thermal stability, and therefore, in a case where the light-emitting layer 5 is formed using a gas phase deposition method, the decomposition of the host material due to heat during deposition can be prevented. Therefore, the light-emitting layer 5 having excellent film quality can be formed. As a result, also from this point of view, the luminous efficiency of the light-emitting element 1 can be increased and also the lifetime thereof can be extended.

In addition, the first tetracene-based compound hardly emits light itself, and therefore, it is also possible to prevent the host material from adversely affecting the emission spectrum of the light-emitting element 1.

Further, the first tetracene-based compound may be either a compound having a heterocyclic skeleton or a compound having no heterocyclic skeleton, but is preferably a compound having a tetracene skeleton with no heterocyclic skeleton.

The compound having a heterocyclic skeleton generally has low durability against holes. Therefore, depending on the type of the first tetracene-based compound having a heterocyclic skeleton, the light-emitting layer 5 shows a tendency to deteriorate due to the holes injected into the light-emitting layer 5, and as a result, the lifetime of the light-emitting element 1 may be shortened.

On the other hand, by using a compound having a tetracene skeleton with no heterocyclic skeleton, in other words, a compound which has a tetracene skeleton in the molecule and also is constituted by a carbon atom and a hydrogen atom as the first tetracene-based compound, the resistance to oxidation and reduction due to injection of holes becomes relatively strong. Therefore, alteration or deterioration due to holes can be suppressed. As a result, the lifetime of the light-emitting element 1 is extended.

Such a first tetracene-based material is not particularly limited as long as it has at least one tetracene skeleton per molecule and has no heterocyclic skeleton, however, it is preferred to use, for example, a compound represented by the following formula IRH1.

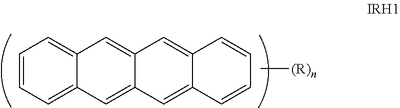

In the formula IRH1, n represents a natural number of 1 to 12, and R each independently represents a hydrogen atom, an alkyl group, an aryl group which may have a substituent, or an arylamino group.

The various types of compounds (the benzo-bis-thiadiazole-based compounds, and the like) exemplified as the light-emitting material as described above have high polarity (large polarization). Therefore, in a case where such a compound is used as the light-emitting material, when the concentration thereof in the light-emitting layer is high, concentration quenching which is a phenomenon in which luminous efficiency is decreased due to the interaction between the molecules of the light-emitting material is likely to occur.

On the other hand, the first tetracene-based compound has low polarity (small polarization). Therefore, by using the first tetracene-based compound as the host material, the interaction between the molecules of the light-emitting material as described above is reduced, and therefore, the concentration quenching property can be reduced.

On the other hand, for example, in a case where Alq₃ having high polarity (large polarization) is used as the host material, the polarity of both the host material and the light-emitting material is high (the polarization is large), and therefore, the interaction between the molecules of the light-emitting material is likely to occur, and thus, the concentration quenching property would be enhanced.

Further, an anthracene-based material which is an acene-based material in the same manner as the first tetracene-based compound has an effect of reducing the concentration quenching property in a case where it is used as the host material, however, the luminous efficiency is decreased as compared with a case where the first tetracene-based compound is used as the host material. It is considered to be because when the anthracene-based material is used as the host material, the energy transfer from the host material to the light-emitting material is not sufficient, and the probability that an electron injected into the LUMO of the host material penetrates toward the anode side is high. In view of this, when the anthracene-based material and the first tetracene-based compound are compared, the first tetracene-based compound is preferably used as the host material, and therefore, in the invention, the first tetracene-based compound is used as the host material.

Accordingly, by using the first tetracene-based compound having a tetracene skeleton as the host material, the luminous efficiency of the light-emitting element 1 can be increased.

Further, the first tetracene-based compound has excellent resistance to electrons and holes. In addition, the first tetracene-based compound also has excellent thermal stability. Due to this, the lifetime of the light-emitting element 1 can be extended. Further, since the first tetracene-based compound has excellent thermal stability, in a case where the light-emitting layer 5 is formed using a gas phase deposition method, the decomposition of the host material due to heat during deposition can be prevented. Therefore, the light-emitting layer 5 having excellent film quality can be formed. As a result, also from this point of view, the luminous efficiency of the light-emitting element 1 can be increased and also the lifetime thereof can be extended.

In addition, the first tetracene-based compound hardly emits light itself, and therefore, it is also possible to prevent the host material from adversely affecting the emission spectrum of the light-emitting element 1.

Further, the first tetracene-based compound to be used as the host material is not particularly limited as long as it is represented by the above formula IRH1 and also can exhibit the function as the host material as described above, however, it is preferred to use a compound represented by the following formula IRH1-A, and it is more preferred to use a compound represented by the following formula IRH1-B.

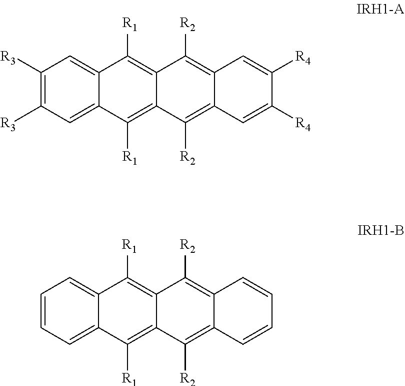

In the formulae IRH1-A and IRH1-B, R₁ to R₄ each independently represent a hydrogen atom, an alkyl group, an aryl group which may have a substituent, or an arylamino group. Further, R₁ to R₄ may be the same as or different from one another.

Further, the first tetracene-based compound (host material) is preferably constituted by a carbon atom and a hydrogen atom. That is, the first tetracene-based compound preferably has a tetracene skeleton with no heterocyclic skeleton. According to this, the polarity of the host material is decreased, and thus, an undesirable interaction between the host material and the light-emitting material can be prevented from occurring. Due to this, the luminous efficiency of the light-emitting element 1 can be increased. In addition, the resistance of the host material to a potential and holes can be increased. As a result, the lifetime of the light-emitting element 1 can be extended.

Specifically, as the first tetracene-based compound, for example, it is preferred to use compounds represented by the following formulae IRH1-1 to IRH1-27.

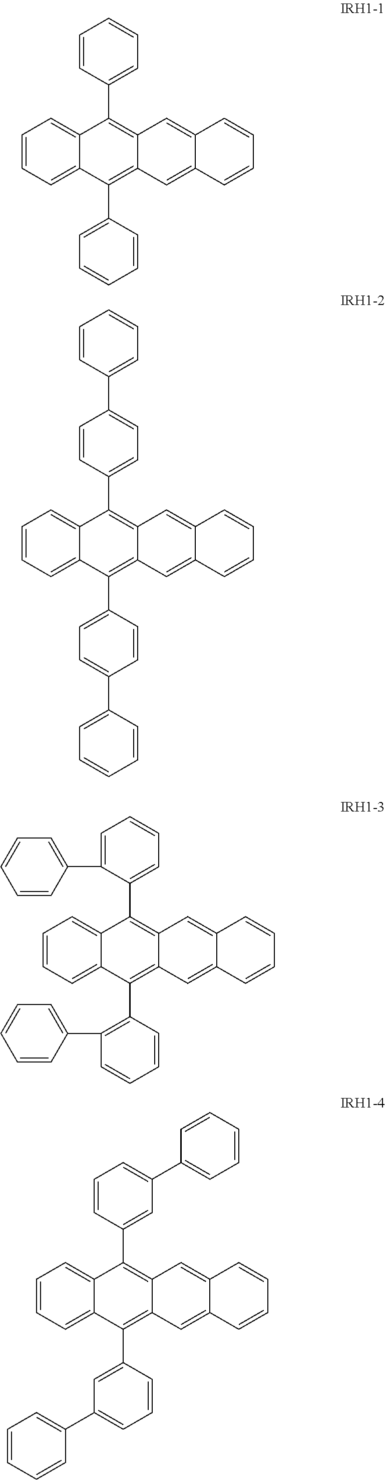

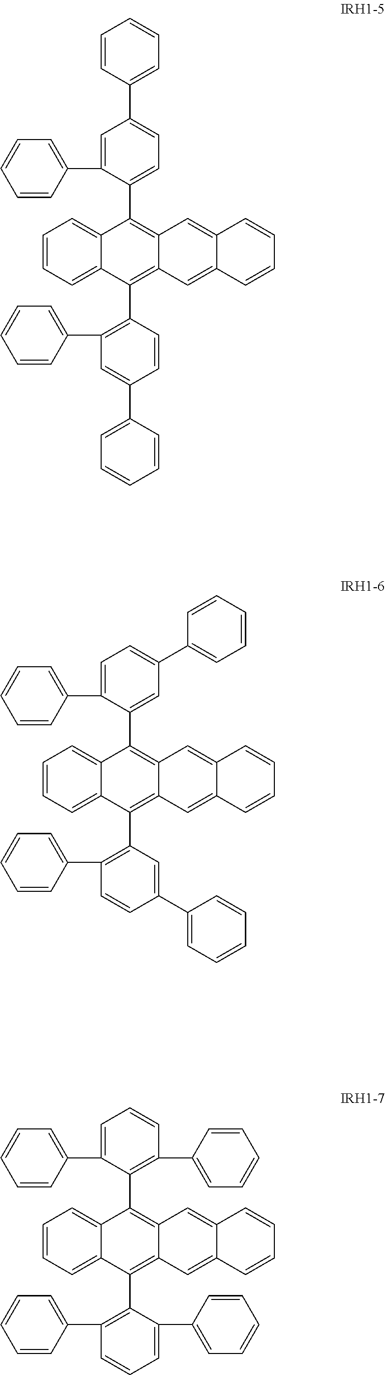

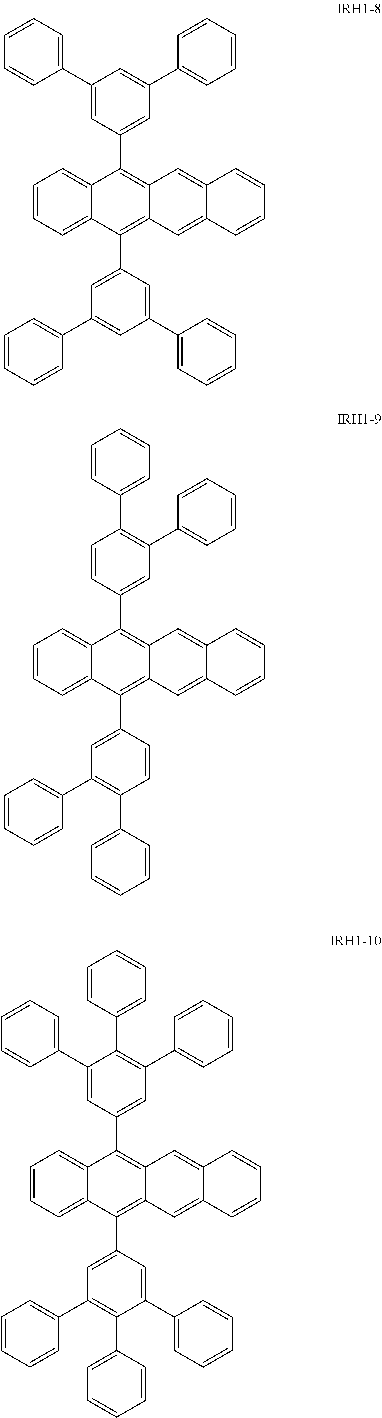

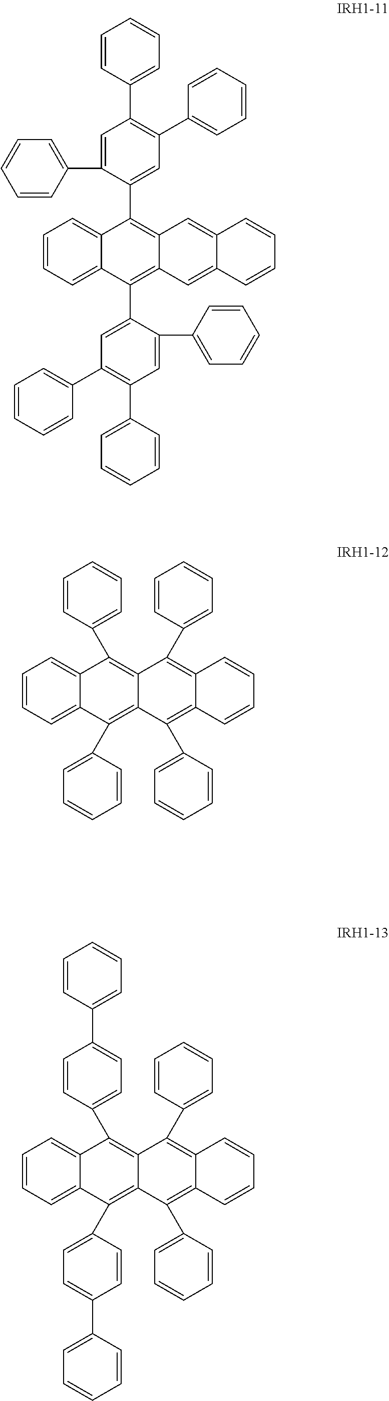

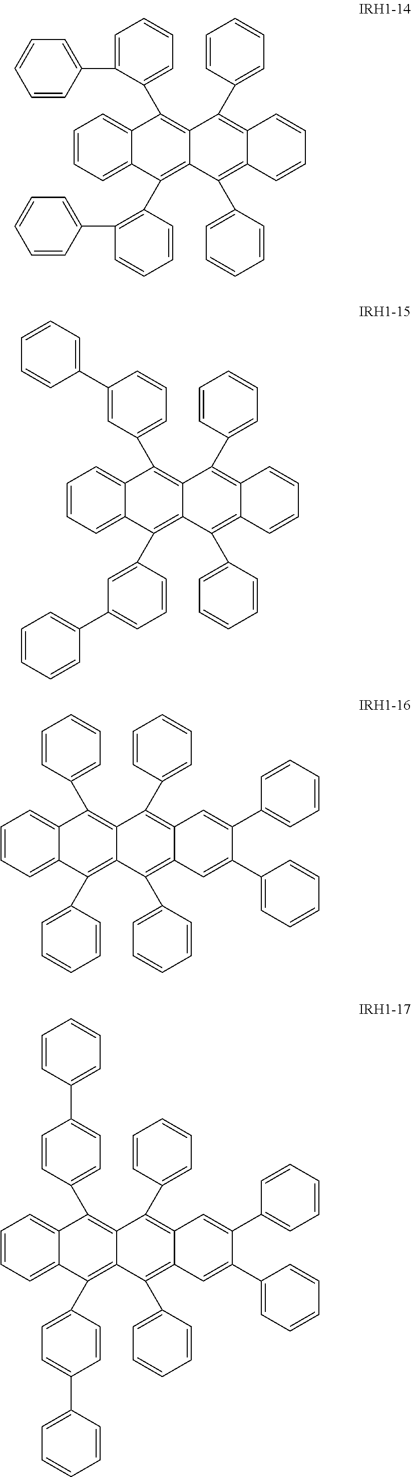

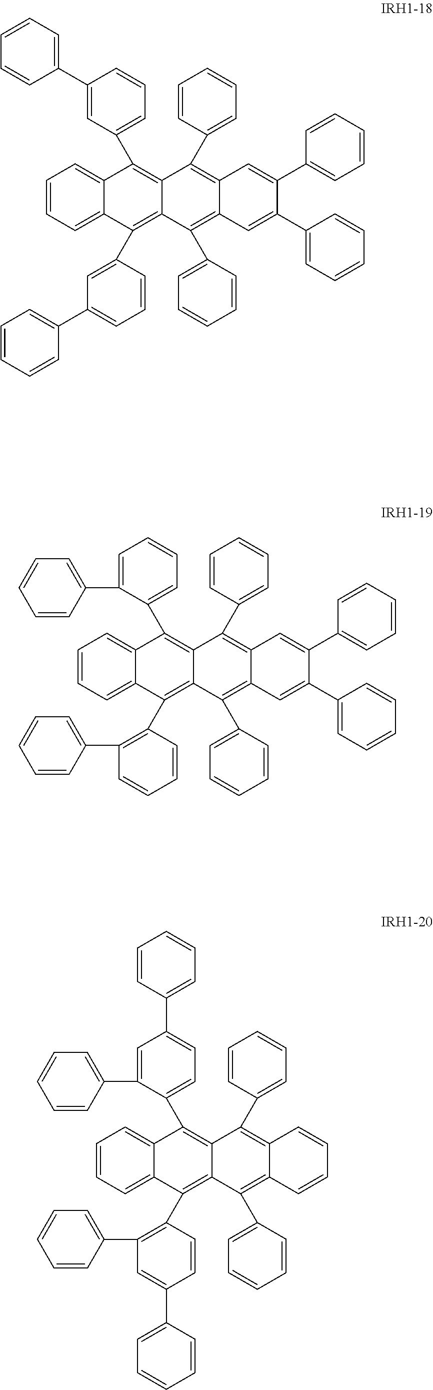

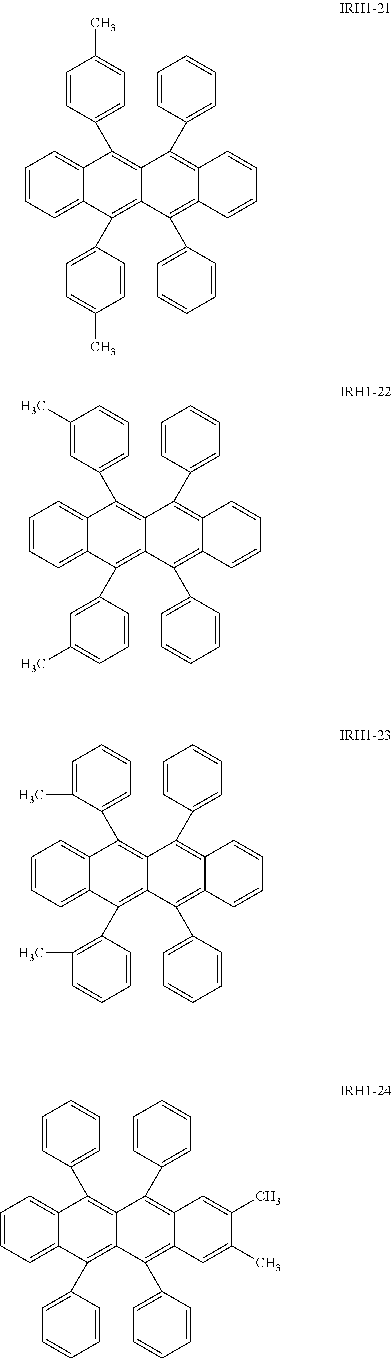

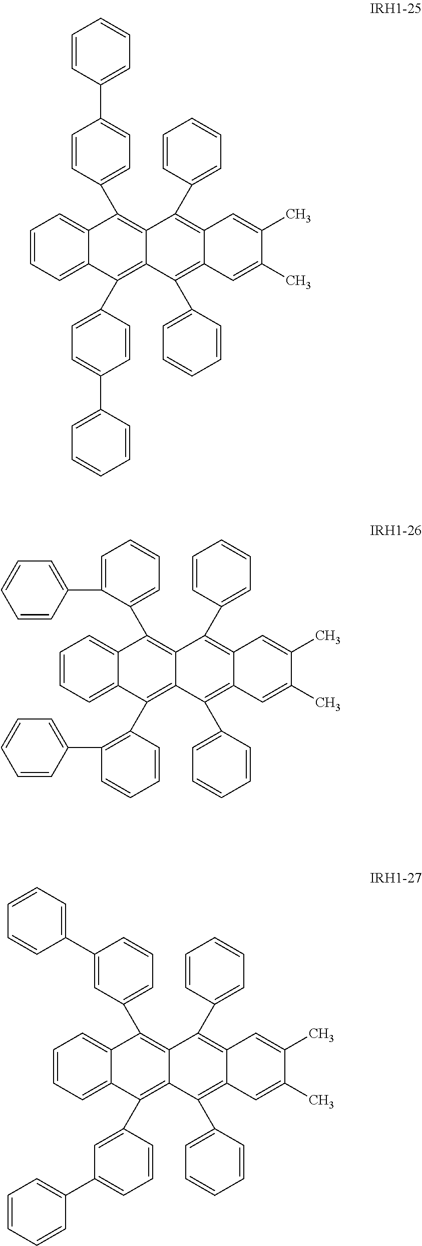

Further, the HOMO of the host material to be used in the light-emitting layer 5 is preferably 5.0 eV or more and 5.8 eV or less, and the LUMO of the host material is preferably 2.5 eV or more and 3.6 eV or less.

The content (doping amount) of the light-emitting material in the light-emitting layer 5 containing such a light-emitting material and a host material is preferably 0.5 wt % or more and 5.0 wt % or less, more preferably 0.75 wt % or more and 2.0 wt % or less, further more preferably 1.5 wt % or more and 2.0 wt % or less. When the content of the light-emitting material is less than the above lower limit, a tendency in which the intensity of light emitted from the host increases is shown depending on the type of the host material. Further, when the content of the light-emitting material exceeds the above upper limit, a tendency in which a decrease in luminous efficiency due to concentration quenching becomes remarkable is sometimes shown depending on the type of the host material, and therefore, by setting the content of the light-emitting material within the above range, an excellent balance between the luminous efficiency and the lifetime of the light-emitting element 1 can be achieved.

The average thickness of the light-emitting layer 5 is preferably 10 nm or more and 50 nm or less, more preferably 25 nm or more and 50 nm or less. When the average thickness of the light-emitting layer 5 is less than the above lower limit, a tendency in which recombination increases in the peripheral layers of the light-emitting layer 5 is shown depending on the type of the light-emitting material, and therefore, unnecessary light emission may increase. Further, when the average thickness of the light-emitting layer 5 exceeds the above upper limit, a tendency in which the voltage in the light-emitting layer 5 gradually increases is shown depending on the type of the light-emitting material, and therefore, a decrease in the luminous efficiency of the light-emitting layer 5 may be caused, and therefore, by setting the thickness of the light-emitting layer 5 within the above range, while suppressing the driving voltage of the light-emitting element 1, the light-emitting element 1 which has high efficiency and a long lifetime can be realized.

### Electron Transport Layer

The electron transport layer 6 is provided between the light-emitting layer 5 and the cathode 8, and has a function to transport electrons injected from the cathode 8 through the electron injection layer 7 to the light-emitting layer 5.

In this invention, as shown in FIG. 1, this electron transport layer 6 includes the first electron transport layer 6b located on the cathode 8 side and the second electron transport layer 6a located on the light-emitting layer 5 side. That is, the electron transport layer 6 includes the first electron transport layer 6b and the second electron transport layer 6a provided between the first electron transport layer 6b and the light-emitting layer 5.

### Second Electron Transport Layer

In the invention, the second electron transport layer 6a contains a second tetracene-based compound having a tetracene skeleton.

Here, in the light-emitting element which emits light in a near-infrared region of 600 nm or more in the related art, in order to prevent holes from coming out of the light-emitting layer, for example, a compound having an anthracene skeleton which is a compound having a deep HOMO of about 6.0 eV is used as the constituent material contained in the electron transport layer or the like which is the adjacent layer on the cathode side.

As the host material contained in the light-emitting layer 5, the first tetracene-based compound having a tetracene skeleton is used for the above-mentioned reasons, however, in this case, due to the high hole transport property of the first tetracene-based compound, holes come out on the cathode 8 side, that is, on the electron transport layer side. At this time, since the electron transport layer contains a compound having an anthracene skeleton, the holes need to jump over a barrier of about 0.3 to 0.4 eV, and as a result, there is a problem that the driving voltage of the light-emitting element is increased.

On the other hand, in the invention, the second electron transport layer 6a adjacent to the light-emitting layer 5 is configured to contain the second tetracene-based compound having a tetracene skeleton so that the HOMO level of the second electron transport layer 6a and the HOMO level of the host material contained in the light-emitting layer 5 are made equal or close to each other. Due to this, the energy barrier, over which holes need to jump in the related art, is lowered. Therefore, the driving voltage of the light-emitting element 1 can be decreased, and as a result, the light-emitting element 1 in which the power consumption is suppressed can be realized. Further, the suppression of the power consumption of the light-emitting element 1 leads to reduction in heat generation (Joule heat) by the driving of the light-emitting element 1, so that the deterioration of the light-emitting element 1 caused by heat generation can be suppressed, and thus, the light-emitting element 1 in which the lifetime is extended can be realized.

Further, the second tetracene-based compound contained in the second electron transport layer 6a has a higher carrier mobility (both hole and electron) as compared with a compound having an anthracene skeleton. Therefore, this is advantageous also to the carrier transport in the second electron transport layer 6a, and also from this point of view, the driving voltage of the light-emitting element 1 can be decreased.

On the other hand, as in the invention, by using the first tetracene-based compound as the host material contained in the light-emitting layer 5, and configuring the second electron transport layer 6a to contain the second tetracene-based compound, the HOMO levels of these layers are made equal or close to each other. Therefore, the confinement efficiency of confining holes injected from the hole injection layer 4 into the light-emitting layer 5 in the light-emitting layer 5 is decreased, and as a result, there is a concern that the luminous efficiency of the light-emitting layer 5 is decreased.

However, in the light-emitting element 1 which emits light in a long wavelength region of 600 nm or more, particularly in a near-infrared region of 700 nm or more, as compared with a light-emitting element which emits visible light (blue to green) in a short wavelength region of less than 600 nm, the HOMO-LUMO gap of the light-emitting material (light-emitting dopant) is small, and therefore, a level carrier (hole) trap is easily generated. Further, in a case where the light-emitting element 1 is particularly applied to an element which emits light in a near-infrared region of 700 nm or more, in the skeleton of the light-emitting material, in order to adjust the HOMO/LUMO levels, an electron-donating group such as triphenylamine or an electron-withdrawing group such as benzothiadiazole are contained. Due to this, also from this point of view, both hole and electron carriers are easily trapped.

In view of this, even if the HOMO level of the first tetracene-based compound contained in the light-emitting layer 5 and the HOMO level of the second tetracene-based compound contained in the second electron transport layer 6a are equal or close to each other, recombination of a hole with an electron is likely to occur in the light-emitting layer 5 containing the light-emitting material which emits light in a long wavelength region of 600 nm or more, and therefore, the decrease in the luminous efficiency of the light-emitting element 1 can be reliably suppressed or prevented.

To summarize the above, in the light-emitting element 1 including the light-emitting layer 5 and the electron transport layer 6 between the anode 3 and the cathode 8, by configuring the light-emitting layer 5 to contain the first tetracene-based compound having a tetracene skeleton functioning as the host material that holds the light-emitting material, and to emit light in a wavelength region of 600 nm or more by applying a current between the anode 3 and the cathode 8, and further configuring the electron transport layer 6 to include the first electron transport layer 6b located on the cathode 8 side and the second electron transport layer 6a located on the light-emitting layer 5 side and containing the second tetracene-based compound having a tetracene skeleton, the driving voltage of the light-emitting element 1 can be decreased, and as a result, the light-emitting element 1 having high luminous efficiency and low power consumption can be provided.

The second tetracene-based compound contained in the second electron transport layer 6a may be either a compound having a heterocyclic skeleton or a compound having no heterocyclic skeleton, but is preferably a compound having a tetracene skeleton with no heterocyclic skeleton.

The compound having a heterocyclic skeleton generally has low durability against holes. Therefore, depending on the type of the second tetracene-based compound having a heterocyclic skeleton, the second electron transport layer 6a shows a tendency to deteriorate due to the holes coming out of the light-emitting layer 5, and as a result, the lifetime of the light-emitting element 1 may be shortened.

On the other hand, by using a compound having a tetracene skeleton with no heterocyclic skeleton, in other words, a compound which has a tetracene skeleton in the molecule and also is constituted by a carbon atom and a hydrogen atom as the second tetracene-based compound, the resistance to oxidation and reduction due to transfer of holes becomes relatively strong. Therefore, alteration or deterioration due to holes can be suppressed. As a result, the lifetime of the light-emitting element 1 is extended.

Further, this second electron transport layer 6a functions as a block layer that prevents holes from reaching the first electron transport layer 6b, and therefore, the alteration or deterioration of the first electron transport layer 6b containing an anthracene-based compound having a nitrogen-containing heterocyclic skeleton due to holes can be suppressed or prevented.

Further, it is preferred that the second tetracene-based compound contained in the second electron transport layer 6a and the first tetracene-based compound functioning as the light-emitting material contained in the light-emitting layer 5 are the same or of the same type. According to this, the HOMO level of the second electron transport layer 6a and the HOMO level of the host material contained in the light-emitting layer 5 can be more reliably made equal or close to each other.

Therefore, as the second tetracene-based material, it is preferred to use a compound represented by the above formula IRH1 as described for the first tetracene-based material.

Specifically, a difference between the HOMO of the second tetracene-based compound of the second electron transport layer 6a and the HOMO of the first tetracene-based compound as the host material to be used in the light-emitting layer 5 is preferably 0.1 eV or less. According to this, it can be said that the HOMO level of the second electron transport layer 6a and the HOMO level of the host material contained in the light-emitting layer 5 are equal or close to each other, and as a result, the driving voltage of the light-emitting element 1 can be decreased, and thus, the light-emitting element 1 in which the power consumption is suppressed is realized.

Further, the HOMO of the second tetracene-based compound is preferably 5.0 eV or more and 5.8 eV or less, and further, the LUMO of the second tetracene-based compound is preferably 2.5 eV or more and 3.6 eV or less.

The average thickness of the second electron transport layer 6a slightly varies also depending on the type of the light-emitting material contained in the light-emitting layer 5, but is preferably 25 nm or more and 200 nm or less, more preferably 50 nm or more and 150 nm or less. According to this, the second electron transport layer 6a can be made to favorably exhibit both functions as the electron transport layer for transporting electrons to the first electron transport layer 6b and as the hole transport layer for transporting holes having passed through the light-emitting layer 5 to the first electron transport layer 6b.

### First Electron Transport Layer

The first electron transport layer 6b contains an anthracene-based compound, which has an anthracene skeleton and a nitrogen-containing heterocyclic skeleton, and has an average thickness of less than 8 nm.

Here, the compound having an anthracene skeleton is a compound having an excellent electron transport property. Further, the compound having a nitrogen-containing heterocyclic skeleton is a compound having an excellent electron injection property from the cathode 8 through the electron injection layer 7. Due to this, by using the anthracene-based compound having an anthracene skeleton and a nitrogen-containing heterocyclic skeleton as the constituent material of the first electron transport layer 6b provided in contact with the electron injection layer 7, the first electron transport layer 6b has both an excellent electron transport property and an excellent electron injection property from the cathode 8 through the electron injection layer 7.

Further, the average thickness of the first electron transport layer 6b is set thin such that it is less than 8 nm.

In the first electron transport layer 6b, the anthracene-based compound having a nitrogen-containing heterocyclic skeleton is used as the constituent material thereof, and the anthracene-based compound shows crystallinity because of having such a nitrogen-containing heterocyclic skeleton. Due to this, when the light-emitting element 1 is used by repeatedly applying a current between the anode 3 and the cathode 8 at a current density of about 500 mA/cm² or more and 2000 mA/cm² or less, the anthracene-based compound shows a tendency to crystallize in the first electron transport layer 6b. In light of this, by setting the average thickness of the first electron transport layer 6b thin such that it is less than 8 nm, the alteration or deterioration of the first electron transport layer 6b due to crystallization of the anthracene-based compound can be suppressed, and as a result, the lifetime of the light-emitting element 1 is extended.

Further, when a hole comes out from the second electron transport layer 6a and even if the hole is injected into the first electron transport layer 6b, since the thickness of the first electron transport layer 6b is thin, the hole further penetrates through the first electron transport layer 6b and disappears in the electron injection layer 7 or the cathode 8. Due to this, also from this point of view, the alteration or deterioration of the first electron transport layer 6b can be suppressed, and as a result, the lifetime of the light-emitting element 1 is extended.

The average thickness of the first electron transport layer 6b is preferably less than 8 nm, but is more preferably 3 nm or more and 5 nm or less. According to this, while exhibiting the function as the first electron transport layer 6b, an effect obtained by setting the film thickness of the first electron transport layer 6b thin can be more remarkably exhibited.

The nitrogen-containing heterocyclic skeleton is not particularly limited as long as it has a nitrogen atom in a heterocyclic ring, however, examples thereof include an azaindolizine skeleton, an oxadiazole skeleton, a pyridine skeleton, a pyrimidine skeleton, a quinoxaline skeleton, and a phenanthroline skeleton such as 2,9-dimethyl-4,7-diphenyl-1,10-phenanthroline (BCP), and above all, an azaindolizine skeleton is preferred. The azaindolizine skeleton is a skeleton having low affinity for a metal material. Therefore, the decrease in the electron transport property and the electron injection property of the first electron transport layer 6b due to the incorporation of an alkali metal, an alkaline earth metal, or the like contained in the electron injection layer 7 in contact with the first electron transport layer 6b can be suppressed or prevented.

Accordingly, as the anthracene-based compound, an azaindolizine-based compound having both an anthracene skeleton and an azaindolizine skeleton in the molecule (hereinafter also simply referred to as “azaindolizine-based compound”) is preferably used. According to this, electrons can be efficiently transported and injected into the second electron transport layer 6a over a long period of time. As a result, the luminous efficiency of the light-emitting element 1 can be increased.

In the azaindolizine-based compound, the number of azaindolizine skeletons and the number of anthracene skeletons contained in one molecule are each preferably one or two. According to this, electrons can be more efficiently transported and injected into the second electron transport layer 6a over a long period of time. As a result, the luminous efficiency of the light-emitting element 1 can be further increased.

Examples of the azaindolizine-based compound include compounds represented by the following general formula ETL1, and more specific examples thereof include compounds represented by the following formulae ETL1-1 to ETL1-24, compounds represented by the following formulae ETL1-25 to ETL1-36, and compounds represented by the following formulae ETL1-37 to ETL1-56.

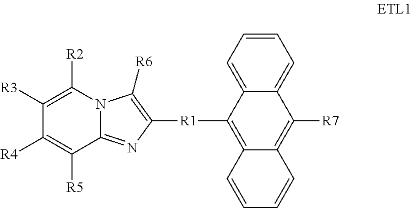

In the formula ETL1, R1 to R7 each independently represent a hydrogen atom, an alkyl group, an aryl group which may have a substituent, or an arylamino group. Further, R1 to R7 may be the same as or different from one another.

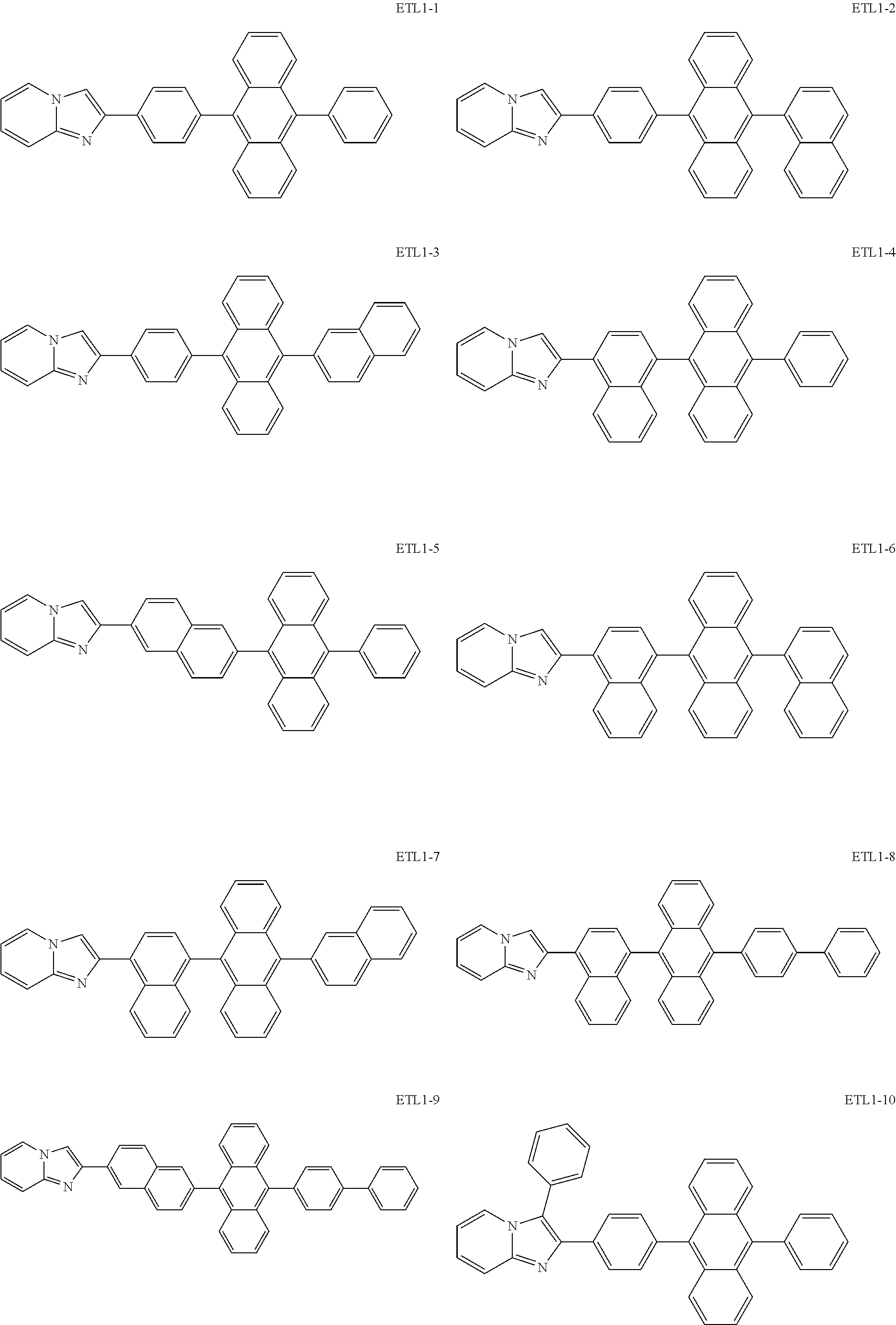

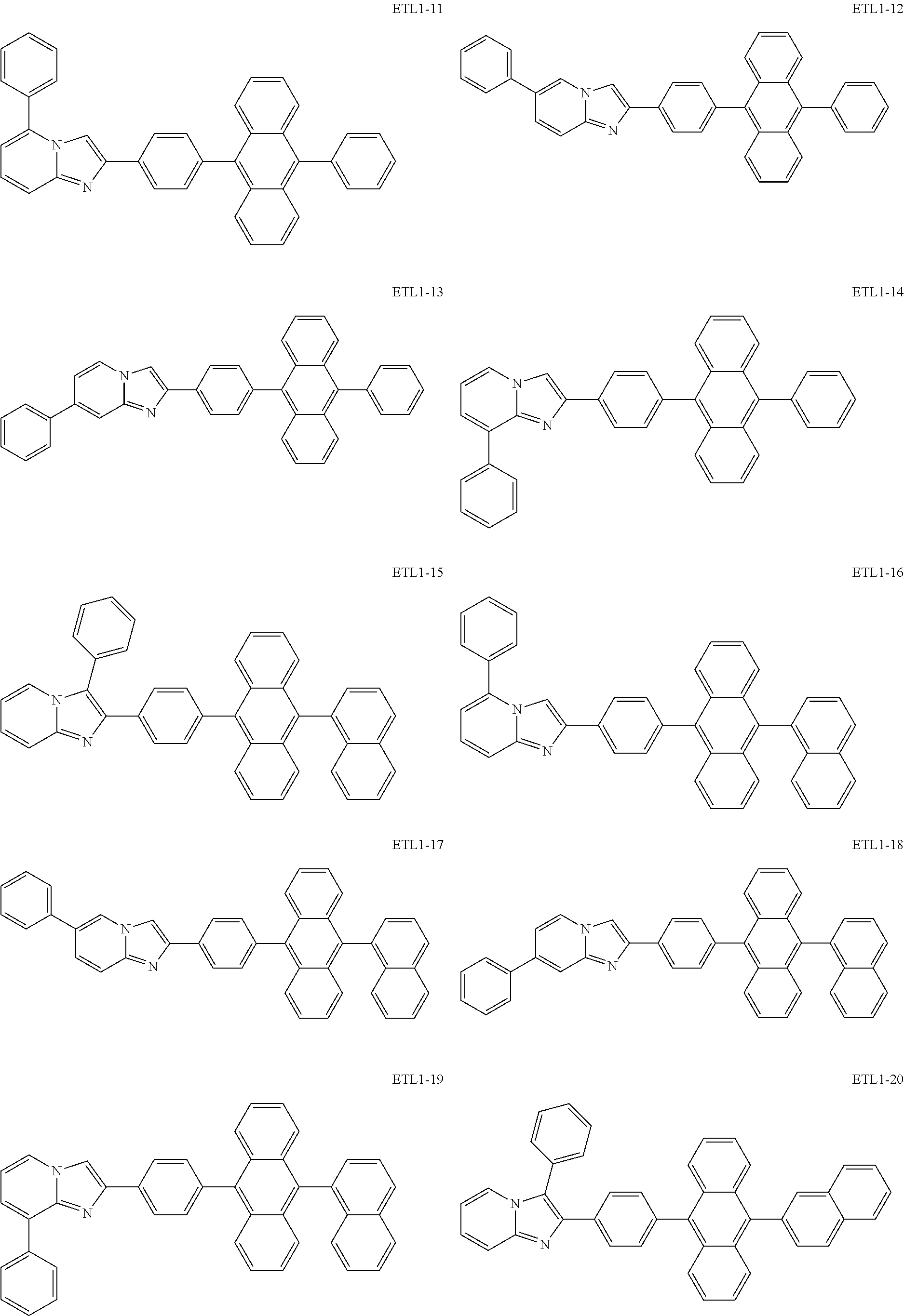

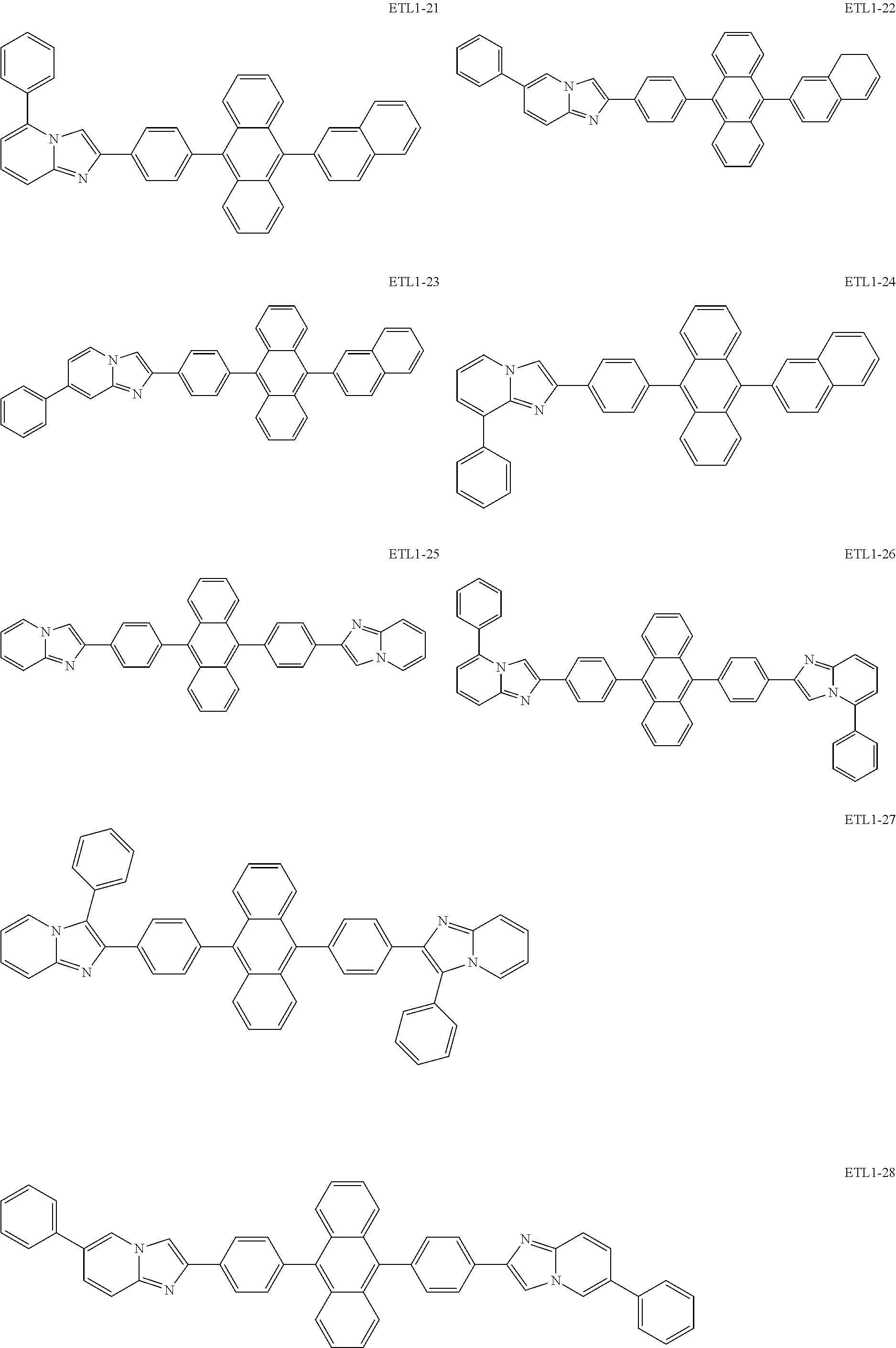

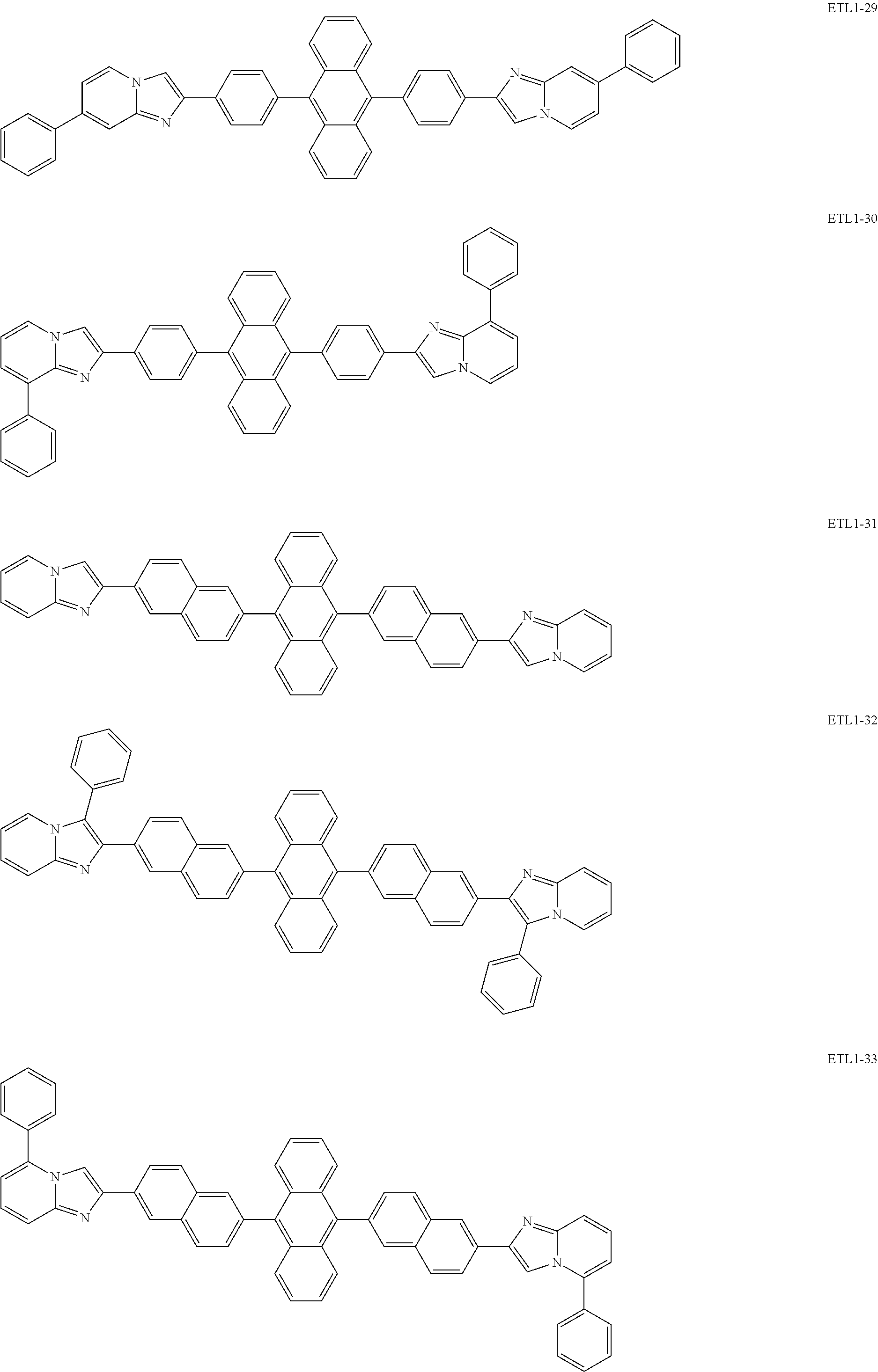

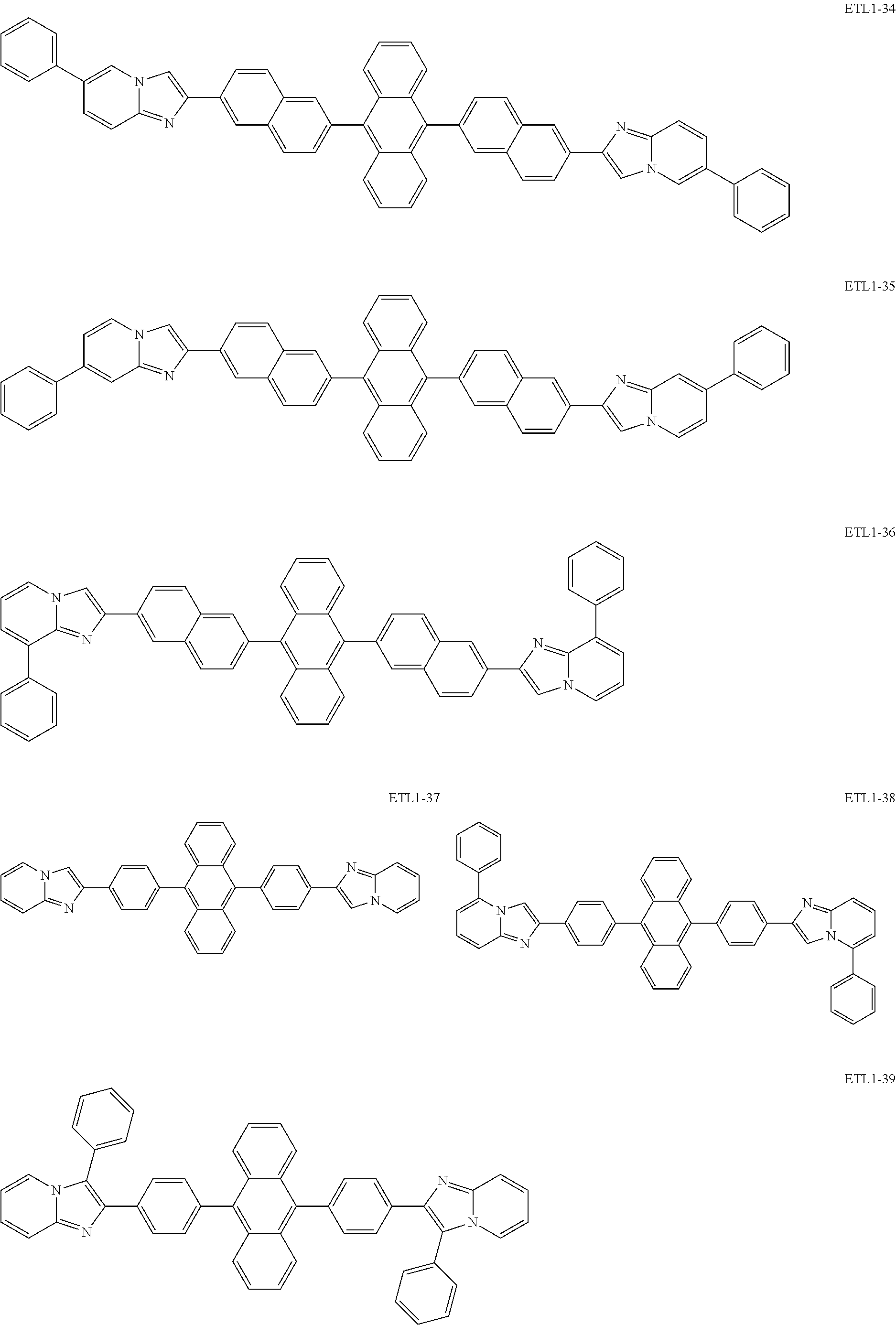

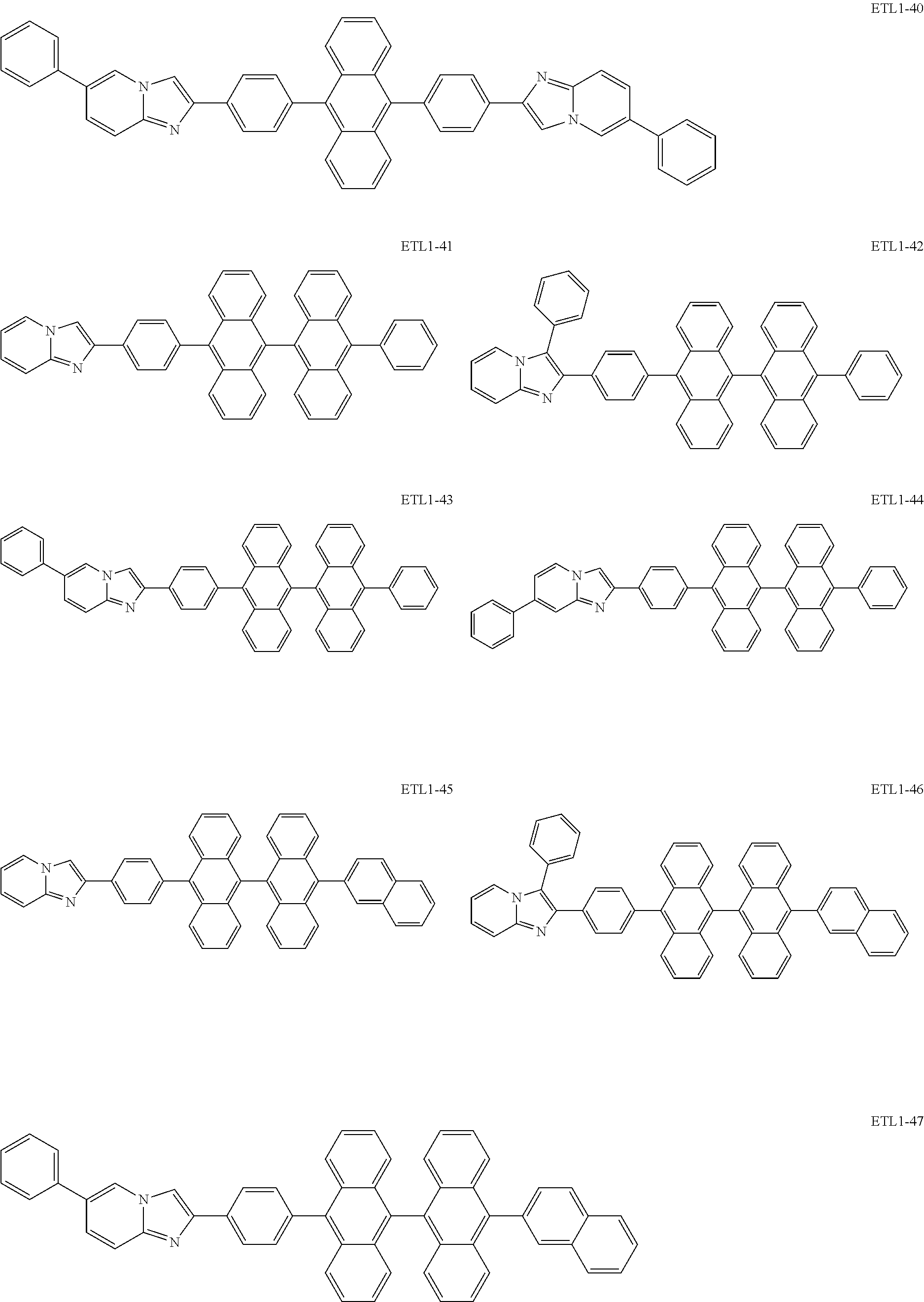

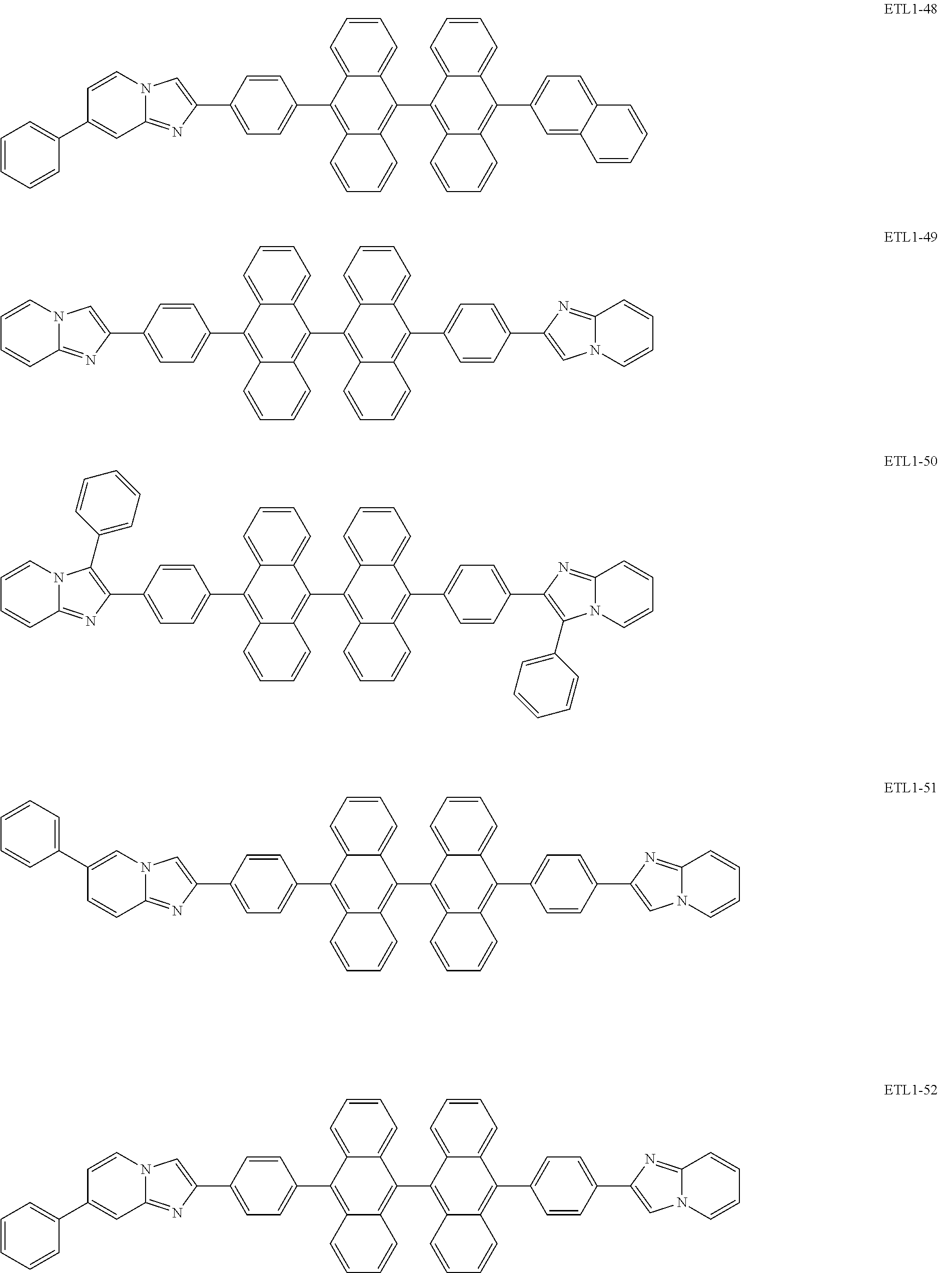

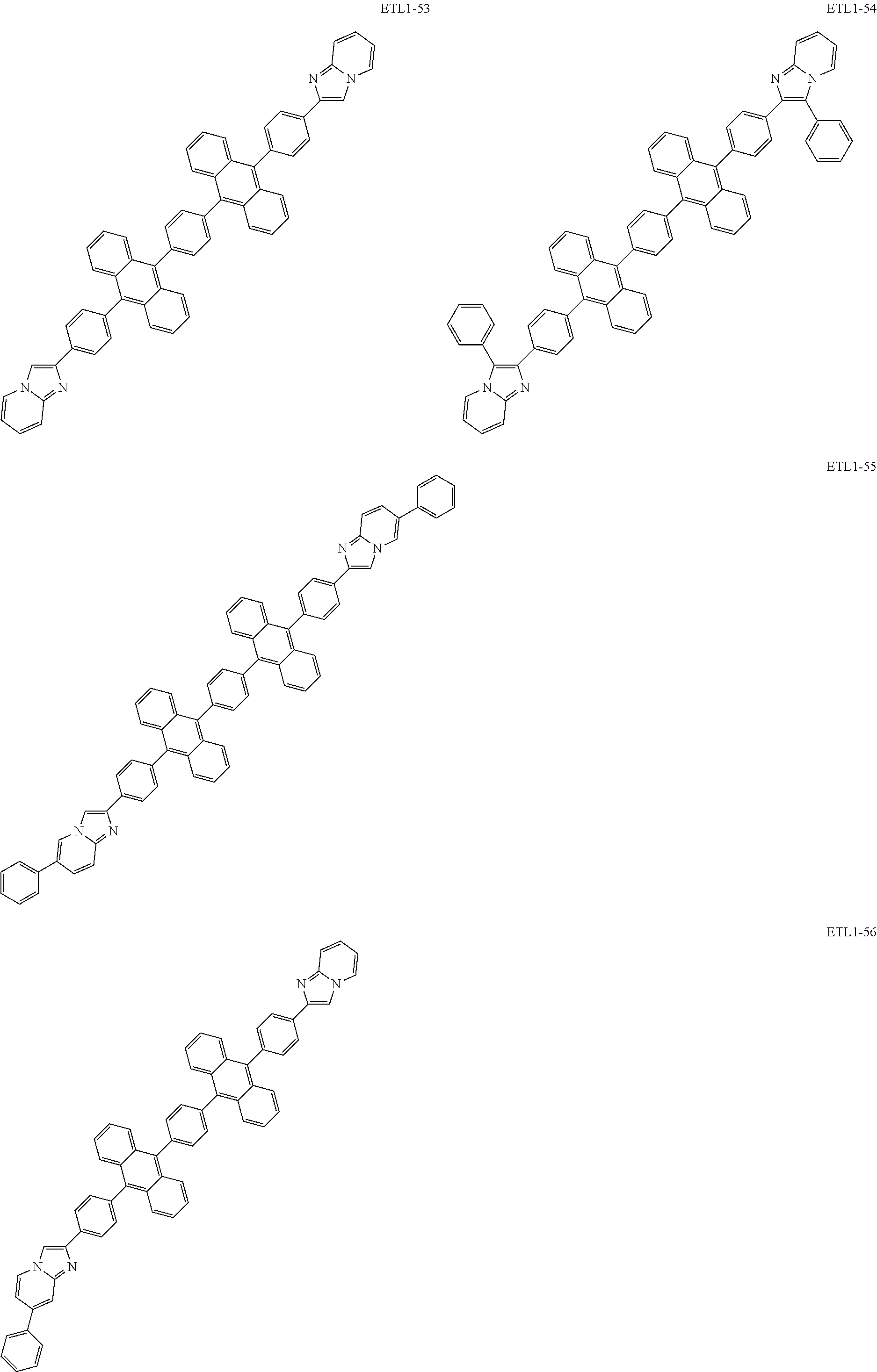

Such an azaindolizine-based compound has an excellent electron transport property and an excellent electron injection property as described above, and the reason for this is considered to be as follows.

The entire molecule of the azaindolizine-based compound having an azaindolizine skeleton and an anthracene skeleton in the molecule as described above is connected by a n-conjugated system, and therefore, the electron cloud is spread across the entire molecule.

The portion of the azaindolizine skeleton of the azaindolizine-based compound has a function to receive an electron and a function to send the received electron to the portion of the anthracene skeleton. On the other hand, the portion of the anthracene skeleton of the azaindolizine-based compound has a function to receive an electron from the portion of the azaindolizine skeleton and a function to transfer the received electron to a layer adjacent to the first electron transport layer 6b on the anode 3 side, that is, to the second electron transport layer 6a.

To be more specific, the portion of the azaindolizine skeleton of the azaindolizine-based compound includes two nitrogen atoms. One of the nitrogen atoms (on the side near the portion of the anthracene skeleton) has an sp² hybrid orbital, and the other nitrogen atom (on the side far from the portion of the anthracene skeleton) has an sp³ hybrid orbital. The nitrogen atom with an sp² hybrid orbital forms a portion of the conjugated system of the azaindolizine-based compound molecule and also has higher electronegativity than a carbon atom, and thus more strongly attracts an electron, and therefore functions as a portion that receives an electron. On the other hand, the nitrogen atom with an sp^{a} hybrid orbital is not a normal conjugated system but has a non-covalent electron pair, and therefore, the electron of the nitrogen atom functions as a portion that sends an electron toward the conjugated system of the azaindolizine-based compound molecule.

On the other hand, the portion of the anthracene skeleton of the azaindolizine-based compound is electrically neutral, and therefore can easily receive an electron from the portion of the azaindolizine skeleton. Further, the portion of the anthracene skeleton of the azaindolizine-based compound has a large orbital overlap with the second tetracene-based compound which is the constituent material of the second electron transport layer 6a, and therefore can easily transfer an electron to the second tetracene-based material.

Such an azaindolizine-based compound has an excellent electron transport property and an excellent electron injection property as described above, and therefore, as a result, the driving voltage of the light-emitting element 1 can be decreased.

The portion of the azaindolizine skeleton is stable even if the nitrogen atom with an sp² hybrid orbital is reduced and also is stable even if the nitrogen atom with an sp³ hybrid orbital is oxidized. Due to this, such an azaindolizine-based compound has high stability against electrons and holes. As a result, the lifetime of the light-emitting element 1 can be extended.

A difference between the HOMO of the constituent material (anthracene-based material) of the first electron transport layer 6b and the HOMO of the constituent material (second tetracene-based material) of the second electron transport layer 6a is preferably 0.2 eV or more, and also a difference between the LUMO of the constituent material (anthracene-based material) of the first electron transport layer 6b and the LUMO of the constituent material (second tetracene-based material) of the second electron transport layer 6a is preferably 0.2 eV or more. According to this, while reducing holes coming out of the second electron transport layer 6a to the first electron transport layer 6b, electrons can be smoothly transported from the first electron transport layer 6b to the second electron transport layer 6a, and therefore, high efficiency of the light-emitting element 1 is achieved.

Also, it is preferred that the electron mobility of the constituent material (anthracene-based material) of the first electron transport layer 6b is smaller than the electron mobility of the constituent material (second tetracene-based material) of the second electron transport layer 6a. According to this, electrons can be smoothly transported from the first electron transport layer 6b to the second electron transport layer 6a.

Further, the HOMO of the constituent material (anthracene-based compound) of the first electron transport layer 6b is preferably 5.8 eV or more and 6.5 eV or less, and the LUMO of the constituent material of the first electron transport layer 6b is preferably 2.8 eV or more and 3.5 eV or less.

Further, it is preferred that the anthracene-based compound and the second tetracene-based compound each have a glass transition temperature (Tg) of 125° C. or higher. According to this, even if the light-emitting element 1 is used by applying a current between the anode 3 and the cathode 8 at a current density of about 500 mA/cm² or more and 2000 mA/cm² or less, fluidization of the electron transport layer 6 (the first electron transport layer 6b and the second electron transport layer 6a) can be suppressed or prevented. Therefore, the decrease in the luminous efficiency of the light-emitting element 1 caused by this is suppressed or prevented.

### Electron Injection Layer

The electron injection layer 7 has a function to improve the electron injection efficiency from the cathode 8.

Examples of the constituent material (electron injection material) of the electron injection layer 7 include various types of inorganic insulating materials and various types of inorganic semiconductor materials.

Examples of such an inorganic insulating material include alkali metal chalcogenides (oxides, sulfides, selenides, and tellurides), alkaline earth metal chalcogenides, alkali metal halides, and alkaline earth metal halides, and among these, it is possible to use one type or two or more types in combination. By constituting the electron injection layer 7 by such a material as a main material, the electron injection property can be further improved. In particular, an alkali metal compound (such as an alkali metal chalcogenide or an alkali metal halide) has a very small work function, and by constituting the electron injection layer 7 using the compound, the light-emitting element 1 can have high luminance.

Examples of the alkali metal chalcogenide include Li₂O, LiO, Na₂S, Na₂Se, and NaO.

Examples of the alkaline earth metal chalcogenide include CaO, BaO, SrO, BeO, BaS, MgO, and CaSe.

Examples of the alkali metal halide include CsF, LiF, NaF, KF, LiCl, KCl, and NaCl.

Examples of the alkaline earth metal halide include CaF₂, BaF₂, SrF₂, MgF₂, and BeF₂.

Further, examples of the inorganic semiconductor material include oxides, nitrides, and oxynitrides containing at least one element selected from Li, Na, Ba, Ca, Sr, Yb, Al, Ga, In, Cd, Mg, Si, Ta, Sb, and Zn, and among these, it is possible to use one type or two or more types in combination.

The average thickness of the electron injection layer 7 is not particularly limited, but is preferably about 0.1 nm or more and 1000 nm or less, more preferably about 0.2 nm or more and 100 nm or less, further more preferably about 0.2 nm or more and 50 nm or less.

The electron injection layer 7 may be omitted depending on the constituent material, thickness, or the like of the cathode 8 and the electron transport layer 6.

### Sealing Member

The sealing member 9 is provided so as to cover the anode 3, the stacked body 14, and the cathode 8, and has a function to hermetically seal these members and block oxygen and moisture. By providing the sealing member 9, an effect of improvement of the reliability of the light-emitting element 1, prevention of the alteration or deterioration (improvement of the durability) of the light-emitting element 1, or the like is obtained.

Examples of the constituent material of the sealing member 9 include Al, Au, Cr, Nb, Ta, Ti, an alloy containing any of these metals, silicon oxide, and various types of resin materials. In a case where a material having electrical conductivity is used as the constituent material of the sealing member 9, in order to prevent a short circuit, it is preferred to provide an insulating film between the sealing member 9 and each of the anode 3, the stacked body 14, and the cathode 8 as needed.

Further, the sealing member 9 may be formed into a flat plate shape and made to face the substrate 2, and a space therebetween may be sealed with, for example, a sealant such as a thermosetting resin.

The light-emitting element 1 as described above can be produced, for example, as follows.

[1] First, a substrate 2 is prepared and an anode 3 is formed on the substrate 2.

The anode 3 can be formed by using, for example, a dry plating method such as a chemical vapor deposition (CVD) method such as plasma CVD or thermal CVD, or vacuum vapor deposition, a wet plating method such as electroplating, a thermal spraying method, a sol-gel method, an MOD method, metal foil joining, or the like.

[2] Subsequently, a hole injection layer 4 is formed on the anode 3.

The hole injection layer 4 is preferably formed by, for example, a gas phase process using a dry plating method such as a CVD method, vacuum vapor deposition, or sputtering, or the like.

The hole injection layer 4 can also be formed by, for example, supplying a hole injection layer-forming material prepared by dissolving a hole injection material in a solvent or dispersing a hole injection material in a dispersion medium onto the anode 3, followed by drying (removal of the solvent or removal of the dispersion medium).

As the method for supplying the hole injection layer-forming material, for example, any of various coating methods such as a spin coating method, a roll coating method, and an ink jet printing method can also be used. The hole injection layer 4 can be relatively easily formed by using such a coating method.

Examples of the solvent or the dispersion medium to be used in the preparation of the hole injection layer-forming material include various types of inorganic solvents, various types of organic solvents, and mixed solvents containing any of these solvents.

The drying can be performed by, for example, leaving the material to stand in an atmosphere at atmospheric pressure or reduced pressure, by a heating treatment, by spraying an inert gas, or the like.

Further, prior to this step, the upper surface of the anode 3 may be subjected to an oxygen plasma treatment. By doing this, lyophilicity can be imparted to the upper surface of the anode 3, an organic substance adhered to the upper surface of the anode 3 can be removed (washed off), the work function near the upper surface of the anode 3 can be adjusted, and so on.

The conditions for the oxygen plasma treatment are, for example, preferably set as follows: the plasma power: about 100 W or more and 800 W or less; the oxygen gas flow rate: about 50 mL/min or more and 100 mL/min or less; and the conveying speed of a member to be treated (anode 3): about 0.5 mm/sec or more and 10 mm/sec or less.

[3] Subsequently, a light-emitting layer 5 is formed on the hole injection layer 4.

The light-emitting layer 5 can be formed by, for example, a gas phase process using a dry plating method such as vacuum vapor deposition, or the like.

[4] Subsequently, an electron transport layer 6 (a first electron transport layer 6b and a second electron transport layer 6a) is formed on the light-emitting layer 5.

It is preferred that the electron transport layer 6 (the first electron transport layer 6b and the second electron transport layer 6a) is formed by, for example, a gas phase process using a dry plating method such as vacuum vapor deposition, or the like.

The electron transport layer 6 can also be formed by, for example, supplying an electron transport layer-forming material prepared by dissolving an electron transport material in a solvent or dispersing an electron transport material in a dispersion medium onto the light-emitting layer 5, followed by drying (removal of the solvent or removal of the dispersion medium).

[5] Subsequently, an electron injection layer 7 is formed on the electron transport layer 6.

In a case where an inorganic material is used as the constituent material of the electron injection layer 7, the electron injection layer 7 can be formed by using, for example, a gas phase process using a dry plating method such as a CVD method, vacuum vapor deposition, or sputtering, or the like, coating and firing of an inorganic fine particle ink, or the like.

[6] Subsequently, a cathode 8 is formed on the electron injection layer 7.

The cathode 8 can be formed by using, for example, a vacuum vapor deposition method, a sputtering method, metal foil joining, coating and firing of a metal fine particle ink, or the like.

The light-emitting element 1 is obtained through the steps as described above.

Finally, a sealing member 9 is placed thereon so as to cover the obtained light-emitting element 1 and joined to the substrate 2.

### Light-Emitting Device

Next, an embodiment of the light-emitting device according to the invention will be described.

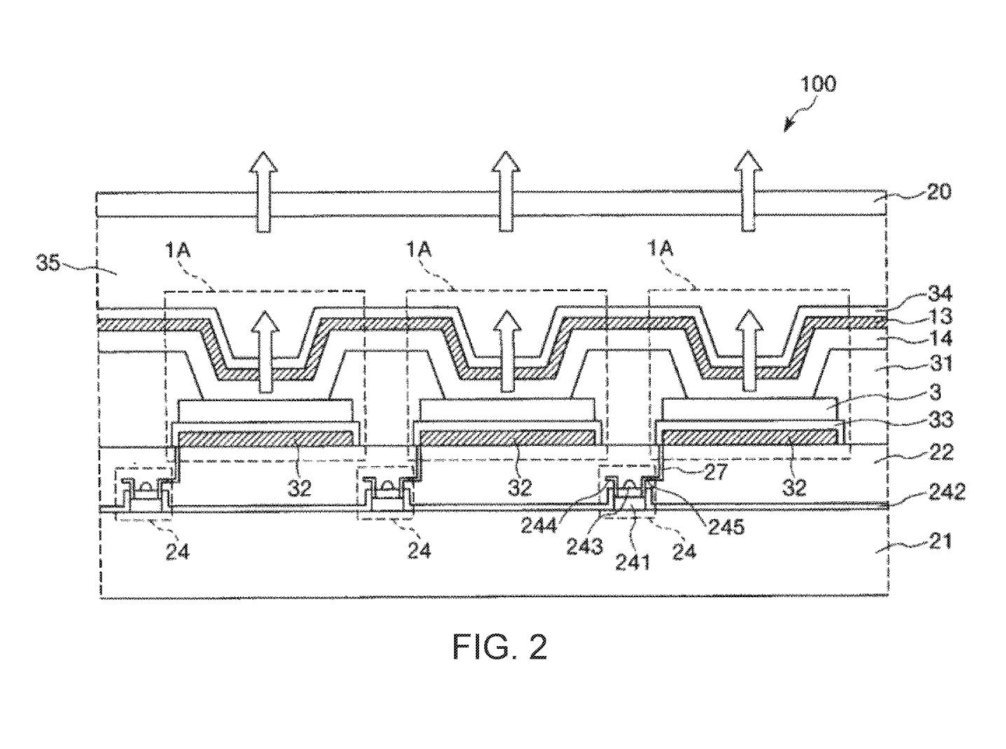

FIG. 2 is a longitudinal cross-sectional view showing an embodiment of a display device to which the light-emitting device according to the invention is applied.

A display device 100 shown in FIG. 2 includes a substrate 21, a plurality of light-emitting elements LA, and a plurality of driving transistors 24 for driving the respective light-emitting elements LA. Here, the display device 100 is a display panel having a top emission structure.

On the substrate 21, the plurality of driving transistors 24 are provided, and a planarization layer 22 constituted by an insulating material is formed so as to cover these driving transistors 24.

Each driving transistor 24 includes a semiconductor layer 241 composed of silicon, a gate insulating layer 242 formed on the semiconductor layer 241, a gate electrode 243 formed on the gate insulating layer 242, a source electrode 244, and a drain electrode 245.

On the planarization layer, the light-emitting elements 1A are provided corresponding to the respective driving transistors 24.

In the light-emitting element 1A, on the planarization layer 22, a reflective film 32, an anticorrosive film 33, an anode 3, a stacked body (organic EL light-emitting section) 14, a cathode 13, and a cathode cover 34 are stacked in this order. In this embodiment, the anode 3 of each light-emitting element 1A constitutes a pixel electrode and is electrically connected to the drain electrode 245 of each driving transistor 24 through an electrically conductive section (wiring) 27. Further, the cathode 13 of each light-emitting element 1A acts as a common electrode.

The light-emitting element 1A in FIG. 2 is the light-emitting element 1 which emits light in a near-infrared region of 600 nm or more.

Between the adjacent light-emitting elements LA, a partition wall 31 is provided. Further, on the light-emitting elements LA, an epoxy layer 35 constituted by an epoxy resin is formed so as to cover the light-emitting elements LA.

On the epoxy layer 35, a sealing substrate 20 is provided so as to cover the epoxy layer 35.

The display device 100 as described above can be used as, for example, a near-infrared display for military purposes or the like.

Such a display device 100 can emit light in a near-infrared region. Further, since the display device 100 includes the light-emitting element 1, which can emit light in a near-infrared region, and in which the power consumption is suppressed, and therefore has excellent reliability.

### Authentication Device

Next, an embodiment of the authentication device according to the invention will be described.

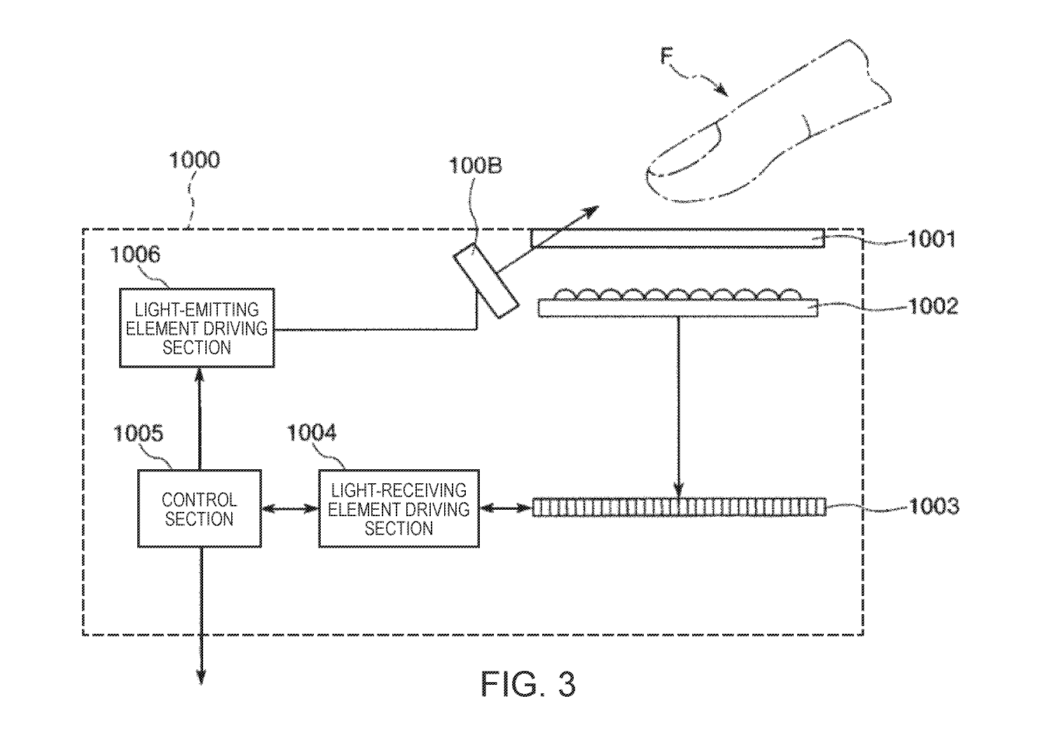

FIG. 3 is a view showing an embodiment of the authentication device according to the invention.

An authentication device 1000 shown in FIG. 3 is a biometric authentication device which authenticates an individual using the biological information of a living body F (in this embodiment, a fingertip).

The authentication device 1000 includes a light source 100B, a cover slip 1001, a microlens array 1002, a light-receiving element group 1003, a light-emitting element driving section 1006, a light-receiving element driving section 1004, and a control section 1005.

The light source 100B includes a plurality of light-emitting elements 1, each of which emits light in a near-infrared region of 600 nm or more, and irradiates light in a near-infrared region onto the living body F which is the object to be imaged. For example, the light-emitting elements 1 of the light source 100B are arranged along the outer circumference of the cover slip 1001.

The cover slip 1001 is a part which the living body F comes into contact with or comes close to.

The microlens array 1002 is provided on the side opposite to the side of the cover slip 1001 which the living body F comes into contact with or comes close to. This microlens array 1002 is constituted by a plurality of microlenses arranged in a matrix.

The light-receiving element group 1003 is provided on the side opposite to the cover slip 1001 with respect to the microlens array 1002. The light-receiving element group 1003 is constituted by a plurality of light-receiving elements provided in a matrix corresponding to the plurality of microlenses of the microlens array 1002. As each light-receiving element of the light-receiving element group 1003, for example, a CCD (Charge Coupled Device), a CMOS, or the like can be used.

The light-emitting element driving section 1006 is a driving circuit which drives the light source 100B.

The light-receiving element driving section 1004 is a driving circuit which drives the light-receiving element group 1003.

The control section 1005 is, for example, an MPU, and has a function to control the driving of the light-emitting element driving section 1006 and the light-receiving element driving section 1004.

Further, the control section 1005 has a function to perform authentication of the living body F by comparison between the light reception result of the light-receiving element group 1003 and the previously stored biometric authentication information.

For example, the control section 1005 forms an image pattern (for example, a vein pattern) associated with the living body F based on the light reception result of the light-receiving element group 1003. Then, the control section 1005 compares the formed image pattern and the image pattern previously stored as the biometric authentication information, and performs authentication (for example, vein authentication) of the living body F based on the comparison result.

Such an authentication device 1000 enables biometric authentication using near-infrared light. Further, the authentication device 1000 includes the light-emitting element 1, which can emit light in a near-infrared region, and in which the power consumption is suppressed as the light source 100B, and therefore has excellent reliability.

Such an authentication device 1000 can be incorporated into various types of electronic apparatuses.

### Electronic Apparatus

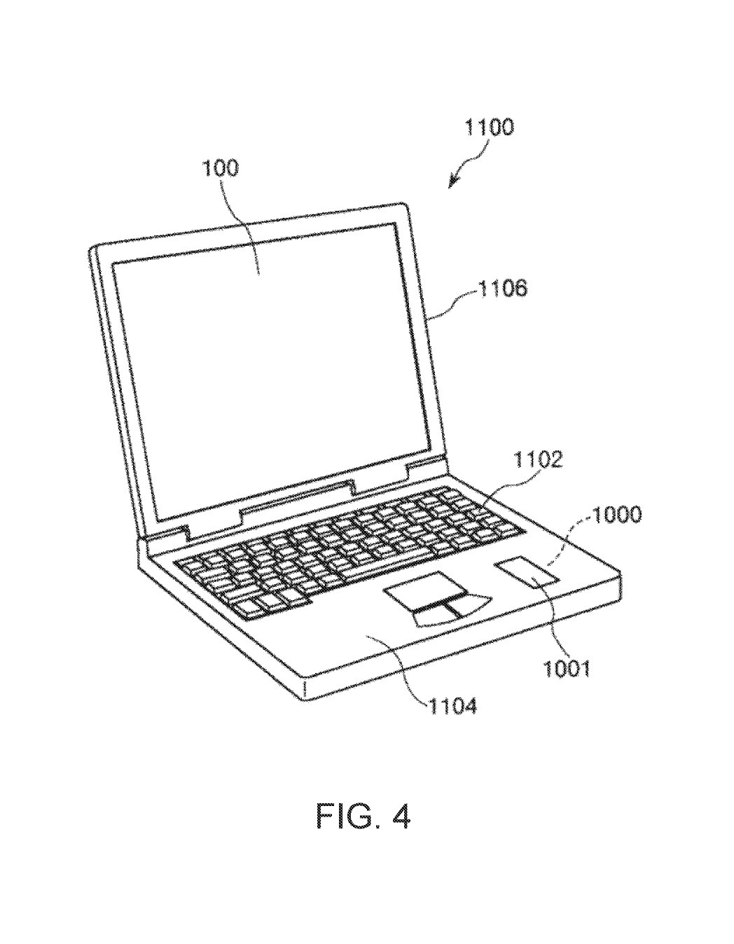

FIG. 4 is a perspective view showing the configuration of a mobile-type (or notebook-type) personal computer to which an electronic apparatus according to the invention is applied.

In this drawing, a personal computer 1100 is configured to include a main body 1104 provided with a keyboard 1102 and a display unit 1106 provided with a display section, and the display unit 1106 is supported rotatably with respect to the main body 1104 through a hinge structure.

In the personal computer 1100, the main body 1104 is provided with the above-mentioned authentication device 1000.

Such a personal computer 1100 includes the light-emitting element 1, which can emit light in a near-infrared region, and in which the power consumption is suppressed, and therefore has excellent reliability.

The electronic apparatus according to the invention can be applied not only to the personal computer (mobile-type personal computer) shown in FIG. 4, but also to, for example, a smartphone, a tablet terminal, a timepiece, a wearable apparatus, a mobile phone, a digital still camera, a television, a video camera, a view finder-type or monitor direct view-type video tape recorder, a laptop-type personal computer, a car navigation device, a pager, an electronic organizer (also including an electronic organizer with a communication function), an electronic dictionary, an electronic calculator, an electronic gaming machine, a word processor, a workstation, a videophone, a security television monitor, electronic binoculars, a POS terminal, an apparatus provided with a touch panel (for example, a cash dispenser in financial institutions and an automatic ticket vending machine), a medical apparatus (for example, an electronic thermometer, a sphygmomanometer, a blood glucose meter, a sphygmometer, a plethysmograph, an electrocardiographic device, an ultrasonic diagnostic device, or a display device for an endoscope), a fish finder, various types of measurement apparatuses, meters and gauges (for example, meters and gauges for vehicles, aircrafts, and ships), a flight simulator, other various types of monitors, a projection-type display device such as a projector, and the like.

Further, examples of the electronic apparatus according to the invention as an apparatus configured to include the above-mentioned light source 100B other than an apparatus configured to include the authentication device 1000 include a medical apparatus (biosensor) such as a blood oximeter, a blood glucose meter, a skin analyzer, a body fat meter, an observation machine for a fluorescent substance in the living body, a skin cancer diagnostic device, a pupil observation device, and a blood vessel observation apparatus, and an infrared scanner apparatus.

In a case where the light-emitting element 1 is applied to the light source 100B included in such a medical apparatus or an infrared scanner apparatus, such an electronic apparatus is required to be small and lightweight, and moreover, in a case where the light-emitting element 1 is applied to a portable electronic apparatus such as a smartphone, a tablet terminal, a timepiece, or a wearable apparatus, an external power supply cannot be used for such an electronic apparatus, and a rechargeable battery needs to be used, and there is a limitation on the discharge capacity of the rechargeable battery to be mounted. Therefore, the light-emitting element 1 in which the power consumption is suppressed is preferably applied thereto.

Further, by suppressing the power consumption of the light-emitting element 1, heat generation by the driving of the light-emitting element 1 can be reduced, however, in a case where the light-emitting element 1 is applied to the light source 100B included in the medical apparatus (biosensor), noise generation due to the heat generation in the light-emitting element 1 can be suppressed, and the accuracy of the medical apparatus (biosensor) is improved. Also from this point of view, the light-emitting element 1 is favorably applied as the light source 100B included in the medical apparatus (biosensor).

Hereinabove, the light-emitting element, the light-emitting device, the light source, the authentication device, and the electronic apparatus according to the invention have been described with reference to the embodiments shown in the drawings, however, the invention is not limited thereto.

The light-emitting element and the light-emitting device according to the invention each may be used as a light source for lighting.

### EXAMPLES

Next, specific examples of the invention will be described.

### 1-1. Production of Light-Emitting Material

A benzo-bis-thiadiazole-based compound represented by the above formula IRD1-2 was synthesized through the following steps.

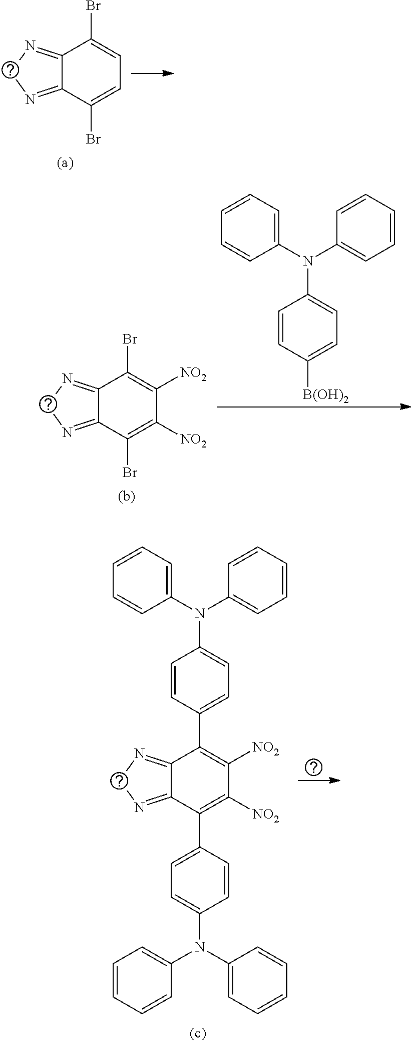 [SMILES: Brc1ccc(Br)c2c1=NCN=2 ; O=[N+]([O-])c1c([N+](=O)[O-])c(Br)c2c(c1Br)=NCN=2 ; OB(O)c1ccc(N(c2ccccc2)c2ccccc2)cc1 ; O=[N+]([O-])c1c([N+](=O)[O-])c(-c2ccc(N(c3ccccc3)c3ccccc3)cc2)c2c(c1-c1ccc(N(c3ccccc3)c3ccccc3)cc1)=NCN=2]

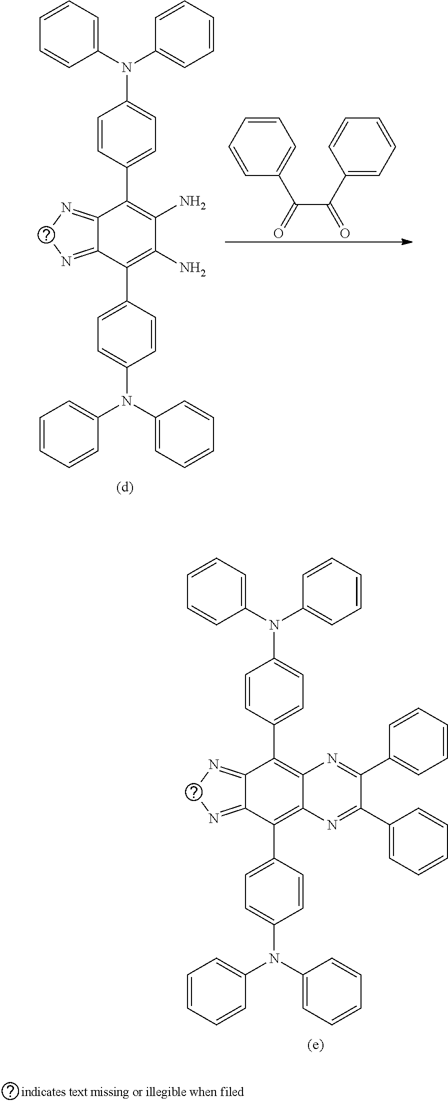 [SMILES: Nc1c(N)c(-c2ccc(N(c3ccccc3)c3ccccc3)cc2)c2c(c1-c1ccc(N(c3ccccc3)c3ccccc3)cc1)=NCN=2 ; O=C(C(=O)c1ccccc1)c1ccccc1 ; c1ccc(-c2nc3c(-c4ccc(N(c5ccccc5)c5ccccc5)cc4)c4c(c(-c5ccc(N(c6ccccc6)c6ccccc6)cc5)c3nc2-c2ccccc2)=NCN=4)cc1]

### Synthesis (A1-1)

In a 5-L flask, 1500 mL of fuming nitric acid was placed and cooled. Thereto, 1500 mL of sulfuric acid was added in divided portions such that the temperature was maintained at 10 to 50° C. Further, 150 g of a compound (a) which is dibromobenzothiadiazole as a starting material was added thereto in small portions over 1 hour. At this time, the temperature of the solution was maintained at 5° C. or lower. After the entire amount was added, a reaction was allowed to proceed at room temperature (25° C.) for 20 hours. After the reaction, the reaction mixture was poured into 3 kg of ice, followed by stirring overnight. Thereafter, the mixture was filtered, followed by washing with methanol and heptane.

The residue after filtration was thermally dissolved in 200 mL of toluene, and the resulting solution was gradually cooled to room temperature and then filtered. The resulting residue was washed with a small amount of toluene, and then dried under reduced pressure.

By doing this, 60 g of a compound (b) (4,7-dibromo-5,6-dinitro-benzo[1,2,5]thiadiazole) with an HPLC purity of 95% was obtained.

### Synthesis (A1-2)

In an Ar atmosphere, in a 5-L flask, 30 g of the compound (b) which is the obtained dibromo compound, 160 g of triphenylamine boronic acid, 2500 mL of toluene, and a 2 M aqueous solution of cesium carbonate (152 g/234 mL of distilled water) were placed, and a reaction was allowed to proceed overnight at 90° C. After the reaction, filtration, liquid separation, and concentration were performed, and 52 g of the resulting crude material was separated using a silica gel column (5 kg of SiO₂), whereby a red-purple solid was obtained.

By doing this, 6 g of a compound (c) (5,6-dinitro-4,7-diphenyl-benzo[1,2,5]thiadiazole) with an HPLC purity of 96% was obtained.

### Synthesis (A1-3)

In an Ar atmosphere, in a 1-L flask, 6 g of the compound (c) which is the obtained dinitro compound, 7 g of reduced iron, and 600 mL of acetic acid were placed, and a reaction was allowed to proceed at 80° C. for 4 hours, and then the mixture was cooled to room temperature. After the reaction, the reaction mixture was poured into 1.5 L of ion exchanged water, and then, 1.5 L of ethyl acetate was further added thereto. After the addition, a solid was deposited, and therefore, 1 L of tetrahydrofuran and 300 g of sodium chloride were added thereto, and liquid separation was performed. The aqueous layer was reextracted with 1 L of tetrahydrofuran, followed by concentration and drying. The resulting residue was again washed with a small amount of water and methanol, whereby an orange solid was obtained.

By doing this, 7 g of a compound (d) (4,7-diphenyl-benzo[1,2,5]thiadiazolo-5,6-diamine) with an HPLC purity of 80% was obtained.

### Synthesis (A1-4)

In an Ar atmosphere, in a 1-L flask, 4.5 g of the compound (d) which is the obtained diamine compound, 3.7 g of benzil, and 300 mL of acetic acid as a solvent were placed, and a reaction was allowed to proceed at 80° C. for 2 hours. After the reaction, the reaction mixture was cooled to room temperature, and then poured into 1 L of ion exchanged water. The resulting crystal was filtered and washed with water, whereby 7 g of a black-green solid was obtained. Then, this black-green solid was purified using a silica gel column (1 kg of SiO₂).

By doing this, 4 g of a compound (e) (a compound represented by the above formula IRD1-2) with an HPLC purity of 99% was obtained. This compound (e) was subjected to mass analysis, and the result was as follows: M+: 492.

Further, the obtained compound (e) was purified by sublimation at a set temperature of 340° C. The HPLC purity of the compound (e) after the purification by sublimation was 99%.

### 1-2. Production of Host Material

A tetracene-based compound represented by the above formula IRH1-2 or the like, and an anthracene-based compound represented by the above formula ETL1-3, the above formula ETL2-30, or the like were synthesized with reference to the production methods described in JP-A-2013-177327 and JP-A-2013-179123, respectively.

### 2. Production of Light-Emitting Element

### Example 1

<1> First, a transparent glass substrate having an average thickness of 0.5 mm was prepared. Subsequently, on this substrate, an ITO electrode (anode) having an average thickness of 100 nm was formed by a sputtering method.

Then, the substrate was subjected to ultrasonic cleaning while immersing the substrate in acetone and 2-propanol in this order, and thereafter subjected to an oxygen plasma treatment and an argon plasma treatment. Each of these plasma treatments was performed at a plasma power of 100 W and a gas flow rate of 20 sccm for a treatment time of 5 sec.

<2> Subsequently, a compound represented by the above formula HIL-1 was deposited on the ITO electrode by a vacuum vapor deposition method, whereby a hole injection layer (HIL) having an average thickness of 70 nm was formed.

<3> Subsequently, the constituent material of a light-emitting layer was deposited on the hole injection layer by a vacuum vapor deposition method, whereby a light-emitting layer having an average thickness of 25 nm was formed. As the constituent material of the light-emitting layer, a compound (benzo-bis-thiadiazole-based compound) represented by the above formula IRD1-2 was used as a light-emitting material (guest material), and a compound (first tetracene-based material) represented by the above formula IRH1-2 was used as a host material. Further, the content (doping concentration) of the light-emitting material (dopant) in the light-emitting layer was set to 2.0 wt %.

<4> Subsequently, a compound (second tetracene-based material) represented by the above formula IRH1-2 was deposited on the light-emitting layer by a vacuum vapor deposition method, whereby a second electron transport layer (ETL2) having an average thickness of 55 nm was formed.

<5> Subsequently, a compound (azaindolizine-based compound) represented by the above ETL1-3 was deposited on the second electron transport layer by a vacuum vapor deposition method, whereby a first electron transport layer (ETL1) having an average thickness of 5 nm was formed.

<6> Subsequently, lithium fluoride (LiF) was deposited on the first electron transport layer by a vacuum vapor deposition method, whereby an electron injection layer having an average thickness of 1 nm was formed.

<7> Subsequently, Al was deposited on the electron injection layer by a vacuum vapor deposition method, whereby a cathode having an average thickness of 100 nm constituted by Al was formed.

<8> Subsequently, a protective cover (sealing member) made of glass was placed thereon so as to cover the respective formed layers, and then fixed and sealed with an epoxy resin.

A light-emitting element was produced through the above-mentioned steps.

### Example 2

A light-emitting element was produced in the same manner as in the above-mentioned Example 1 except that a compound represented by the above formula ETL2-3 was used as the compound used for forming the second electron transport layer in the step <4>.

### Example 3

A light-emitting element was produced in the same manner as in the above-mentioned Example 1 except that a compound represented by the above formula (RD-1) was used as the light-emitting material (dopant) used in the step <3>.

### Comparative Example 1

A light-emitting element was produced in the same manner as in the above-mentioned Example 1 except that a compound represented by the above formula ETL1-3 was used as the compound used for forming the second electron transport layer in the step <4>.

### Comparative Example 2

A light-emitting element was produced in the same manner as in the above-mentioned Example 1 except that a compound represented by the above formula ETL2-30 was used as the compound used for forming the second electron transport layer in the step <4>.

### Comparative Example 3

A light-emitting element was produced in the same manner as in the above-mentioned Example 1 except that a compound represented by the above formula IRH1-2 was used as the compound used for forming the first electron transport layer in the step <5>.

### Comparative Example 4

A light-emitting element was produced in the same manner as in the above-mentioned Example 1 except that a compound represented by the above formula ETL2-30 was used as the host material used in the step <3> and also as the compound used for forming the second electron transport layer in the step <4>.

### Comparative Example 5

A light-emitting element was produced in the same manner as in the above-mentioned Example 1 except that a compound represented by the following formula (GD-1) was used as the light-emitting material (dopant) used in the step <3>.

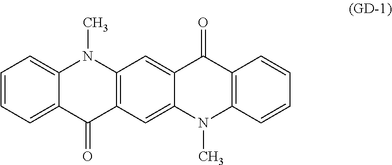 [SMILES: Cn1c2ccccc2c(=O)c2cc3c(cc21)c(=O)c1ccccc1n3C]

### 3. Evaluation

With respect to the respective Examples and the respective Comparative Examples, a current of 3.0 mA was allowed to flow through each of the light-emitting elements using a constant current power supply (KEITHLEY 2400, manufactured by TOYO Corporation), and the driving voltage, emission wavelength (emission peak wavelength), and emission power at that time were measured using a high-speed spectroradiometer (S-9000, manufactured by Soma Optics Co., Ltd.), and power efficiency was determined from the emission power and the supplied power.

Further, a constant current of 100 mA/cm² was allowed to flow through each of the light-emitting elements, and a time until the luminance decreased to 80% of the initial luminance (LT80) was also measured.

These measurement results are shown in Table 1.

TABLE 1

| | | | | | Material | | | | |
|---|---|---|---|---|---|---|---|---|---|
| | Film thickness (nm) | | | | | Light-emitting layer | | | |
| | | Light- | | | | Light- | Doping | | |
| | | emitting | | | | emitting | concentration | | |
| | HIL | layer | ETL2 | ETL1 | HIL | material | (wt %) | Host | ETL2 |
| Example 1 | 70 | 25 | 55 | 5 | HIL-1 | IRD1-2 | 2.0 | IRH1-2 | IRH1-2 |
| Example 2 | | | | | | | | | ETL2-3 |
| Example 3 | | | | | | RD-1 | | | IRH1-2 |
| Comparative | 70 | 25 | 55 | 5 | HIL-1 | IRD1-2 | 2.0 | IRH1-2 | ETL1-3 |
| Example 1 | | | | | | | | | |
| Comparative | | | | | | | | | ETL2-30 |
| Example 2 | | | | | | | | | |
| Comparative | | | | | | | | | IRH1-2 |
| Example 3 | | | | | | | | | |
| Comparative | | | | | | | | ETL2-30 | ETL2-30 |
| Example 4 | | | | | | | | | |
| Comparative | | | | | | GD-1 | | IRH1-2 | IRH1-2 |
| Example 5 | | | | | | | | | |

| | | | OLED characteristics | | | | |
|---|---|---|---|---|---|---|---|
| | | | | | Power | | |
| | | Measurement | | | efficiency | | |
| | | conditions | Driving | | (emission PW/ | Emission | |
| | Material | Supplied | voltage | Emission | supplied | wavelength | LT80 |
| | ETL1 | current (mA) | (V) | PW (%) | power) | (nm) | (hr) |
| Example 1 | ETL1-3 | 3.0 | 3.8 | 0.176 | 1.54% | 760 | 1100 |
| Example 2 | | | 4.0 | 0.169 | 1.41% | 760 | 700 |
| Example 3 | | | 3.9 | 0.283 | 2.42% | 610 | 1150 |
| Comparative | ETL1-3 | 3.0 | 6.2 | 0.143 | 0.77% | 760 | <100 |
| Example 1 | | | | | | | |
| Comparative | | | 5.5 | 0.184 | 1.12% | 760 | 1070 |
| Example 2 | | | | | | | |
| Comparative | IRH1-2 | | 8.6 | 0.013 | 0.05% | 760 | <100 |
| Example 3 | | | | | | | |
| Comparative | ETL1-3 | | 6.3 | 0.105 | 0.56% | 760 | <100 |
| Example 4 | | | | | | | |
| Comparative | | | 4.1 | 0.041 | 0.33% | 530 | 1000 |
| Example 5 | | | | | | | |

As apparent from Table 1, it can be said that by using a material which allows the light-emitting layer to emit light in a wavelength region of 600 nm or more as the light-emitting material, and further, by using the first tetracene-based compound as the host material and configuring the second electron transport layer to contain the second tetracene-based compound in each of the light-emitting elements of the respective Examples, the driving voltage is decreased and suppression of power consumption is achieved as compared with the light-emitting elements of the respective Comparative Examples.

The entire disclosure of Japanese Patent Application No. 2017-048284 is hereby incorporated herein by reference.

What is claimed is:

1. A light-emitting element, comprising:
an anode;
a cathode;
a light-emitting layer which is provided between the anode and the cathode, contains a light-emitting material and a first tetracene-based compound having a tetracene skeleton functioning as a host material that holds the light-emitting material, and emits light in a wavelength region of 600 nm or more by applying a current between the anode and the cathode; and
an electron transport layer which is provided between the light-emitting layer and the cathode, and includes a first electron transport layer located on the cathode side and a second electron transport layer located on the light-emitting layer side and containing a second tetracene-based compound having a tetracene skeleton.

2. The light-emitting element according to claim 1, wherein the first tetracene-based compound and the second tetracene-based compound are the same or of the same type.

3. The light-emitting element according to claim 1, wherein the first tetracene-based compound and the second tetracene-based compound each have a tetracene skeleton with no heterocyclic skeleton.

4. The light-emitting element according to claim 1, wherein the first electron transport layer contains an anthracene-based compound having an anthracene skeleton and a nitrogen-containing heterocyclic skeleton, and has an average thickness of less than 8 nm.

5. The light-emitting element according to claim 1, wherein a difference between the HOMO of the first tetracene-based compound and the HOMO of the second tetracene-based compound is 0.1 eV or less.

6. The light-emitting element according to claim 1, wherein the second electron transport layer has an average thickness of 25 nm or more and 200 nm or less.

7. The light-emitting element according to claim 1, wherein the light-emitting element is used by applying a current between the anode and the cathode at a current density of 500 mA/cm² or more and 2000 mA/cm² or less.

8. A light-emitting device, comprising the light-emitting element according to claim 1.

9. A light-emitting device, comprising the light-emitting element according to claim 2.

10. A light-emitting device, comprising the light-emitting element according to claim 3.

11. A light-emitting device, comprising the light-emitting element according to claim 4.

12. A light source, comprising the light-emitting element according to claim 1.

13. A light source, comprising the light-emitting element according to claim 2.

14. A light source, comprising the light-emitting element according to claim 3.

15. An authentication device, comprising the light-emitting element according to claim 1.

16. An authentication device, comprising the light-emitting element according to claim 2.

17. An authentication device, comprising the light-emitting element according to claim 3.

18. An electronic apparatus, comprising the light-emitting element according to claim 1.

19. An electronic apparatus, comprising the light-emitting element according to claim 2.

20. An electronic apparatus, comprising the light-emitting element according to claim 3.
